(19) United States
(12) Patent Application Publication
(10) Pub. No.: US 2018/0288867 A1
(43) Pub. Date: Oct. 4, 2018

(54) SURFACE TREATED COPPER FOIL, LAMINATE USING THE SAME, COPPER FOIL WITH CARRIER, PRINTED WIRING BOARD, ELECTRONIC DEVICE, AND METHOD FOR MANUFACTURING PRINTED WIRING BOARD

(71) Applicant: JX Nippon Mining & Metals Corporation, Tokyo (JP)

(72) Inventor: Ryo Fukuchi, Ibaraki (JP)

(21) Appl. No.: 15/939,818

(22) Filed: Mar. 29, 2018

(30) Foreign Application Priority Data
Mar. 31, 2017 (JP) 2017-073280

(51) Int. Cl. H05K 1/02; H05K 3/02; H05K 3/46; B32B 15/08; B32B 15/20

(52) U.S. Cl. CPC H05K 1/0242; B32B 2457/08; H05K 3/4682; H05K 3/4652; B32B 15/08; B32B 15/20; H05K 2201/0379; H05K 2201/0338; H05K 2201/0355; H05K 2201/0382; H05K 2201/0391; H05K 2201/0358; H05K 2203/0152; H05K 2203/0156; H05K 2203/016; B32B 2250/02; B32B 2250/03; B32B 2255/06; B32B 2367/00; B32B 2255/205; H05K 3/025

(57) ABSTRACT

The invention provides a surface treated copper foil with which transmission loss is favorably suppressed even if the surface treated copper foil is used for a high frequency circuit board.

A surface treated copper foil has a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rz on a side of the surface treated layer measured by a contact type roughness meter is 1.3 μm or less.

### TECHNICAL FIELD

One or more embodiments of the present application relates to a surface treated copper foil, a laminate using the surface treated copper foil, a carrier-attached copper foil, a printed wiring board, an electronic device, and a method for manufacturing a printed wiring board.

### BACKGROUND ART

Printed wiring boards have made a significant progress over the past half century and are used in almost all electronic devices nowadays. In recent years, with the increasing needs for downsizing and higher performance of electronic devices, higher density packaging of mounted components and higher-frequency signal transmission have advanced, and as a result, printed wiring boards now need to better handle signal transmission at higher frequencies.

A substrate for higher frequencies is required to keep transmission loss as small as possible to ensure the quality of output signals. The transmission loss is mainly divided into two losses: dielectric loss that is caused by a resin (substrate side) and conductor loss that is caused by a conductor (copper foil side). The dielectric loss is reduced as the dielectric constant and the dielectric tangent (DF) become smaller. In high-frequency signals, the main causes of the conductor loss is that a cross-sectional area that the electric current flows is reduced and the resistance is increased due to the skin effect that is the tendency such that the electric current flows nearer to the surface of a conductor as the frequency becomes higher.

As a technology to reduce the transmission loss in a copper foil for high frequency circuits, Patent Literature 1, for example, discloses a metal foil for a high frequency circuit in which one side or both sides of the metal foil is/are coated with silver or a silver alloy, and a coating layer of a metal other than silver or a silver alloy is provided on the silver or the silver alloy coated layer in a manner that the thickness of the coating layer is thinner than that of the silver or the silver alloy coated layer. According to Patent Literature 1, it is possible to provide a metal foil in which the loss due to the skin effect is reduced even in super high frequency bands that are used in satellite communication.

Patent Literature 2 discloses a roughened rolled copper foil for high frequency circuits that is a material for a printed circuit board and is characterized in that the integrated intensity (I(200)) of the (200) plane obtained by X-ray diffraction on a rolled surface of a rolled copper foil after recrystallization annealing and the integrated intensity (I₀(200)) of the (200) plane obtained by X-ray diffraction of fine powder copper satisfy a relation of I(200)/I₀(200)>40, and after the rolled surface undergoes a roughening treatment by electroplating, the roughened surface has the arithmetic average roughness (hereinafter referred to as Ra) of 0.02 μm-0.2 μm and the ten-point average roughness (hereinafter referred to as Rz) of 0.1 μm-1.5 μm. According to Patent Literature 2, it is possible to provide a printed circuit board that can be used in a high frequency band over 1 GHz.

Moreover, Patent Literature 3 discloses an electrolytic copper foil characterized in that a part of a surface of the copper foil is a rugged surface of 2-4 μm in surface roughness and is composed of bunchy projections. According to Patent Literature 3, it is possible to provide an electrolytic copper foil that has good high frequency transmission characteristics.

### CITATION LIST

### Patent Literature

Patent Literature 1: Japanese Patent No. 4161304

Patent Literature 2: Japanese Patent No. 4704025

Patent Literature 3: Japanese Patent Laid-Open Application No. 2004-244656

### SUMMARY OF INVENTION

### Technical Problem

The conductor loss caused by a conductor (copper foil side) results from increase in resistance due to the skin effect as described above, but this resistance is not only the resistance of the copper foil itself but also is affected by the resistance of a surface treated layer formed by a roughening treatment applied to ensure adhesiveness between the surface of the copper foil and a resin substrate. More specifically, it has been known that the surface roughness of the copper foil is the main cause of the conductor loss, and the transmission loss would be decreased as the roughness becomes smaller.

When a roughening treatment is conducted as a surface treatment of a copper foil, a Cu—Ni alloy treatment or a Cu—Co—Ni alloy treatment is usually used, and when a heat-resistant treatment and a rustproofing treatment is conducted as a surface treatment of a copper foil, a Ni—Zn alloy treatment or a Co—Ni alloy treatment is usually used.

However, Co and Ni, and Fe, which are usually used in the roughening treatment, the heat-resistant treatment, and the rustproofing treatment, are metals that exhibit the ferromagnetic property at room temperature. When any of such metals is contained in a surface treated layer as a component, current distribution and magnetic field distribution in a conductor are affected by the magnetic property, which causes such a problem that the transmission property of the copper foil is degraded.

Accordingly, it is an object of one or more embodiments of the present application to provide a surface treated copper foil in which the transmission loss is favorably suppressed even when the surface treated copper foil is used in a high frequency circuit board.

### Means for Solving the Problem

The inventors of one or more embodiments of the present application have found out that the high frequency conductor loss can be reduced by controlling the total deposition amount of Co, Ni, and Mo on a surface treated layer of a copper foil to a prescribed amount or less to control the effect of the ferromagnetic metals on the transmission property and the high frequency conductor loss can be further reduced by forming particles with a prescribed form on the surface treated layer.

One aspect of one or more embodiments of the present application created on the basis of the above findings is a surface treated copper foil including a surface treated layer formed on at least one surface, and the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rz on a side of the surface treated layer measured by a contact type (stylus) roughness meter is 1.3 μm or less.

Another aspect of one or more embodiments of the present application is a surface treated copper foil including a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rp on a side of the surface treated layer measured by a laser microscope is 1.59 μm or less.

Another aspect of one or more embodiments of the present application is a surface treated copper foil including a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rv on the surface treated layer side measured by a laser microscope is 1.75 μm or less.

Another aspect of one or more embodiments of the present application is a surface treated copper foil including a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rzjis on the surface treated layer side measured by a laser microscope is 3.3 μm or less.

Another aspect of one or more embodiments of the present application is a surface treated copper foil including a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rc on the surface treated layer side measured by a laser microscope is 1.0 μm or less.

Another aspect of one or more embodiments of the present application is a surface treated copper foil including a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Ra on the surface treated layer side measured by a laser microscope is 0.4 μm or less.

Another aspect of one or more embodiments of the present application is a surface treated copper foil including a surface treated layer formed on at least one surface, the total deposition amount of Co, Ni, and Mo is 1000 μg/dm² or less in the surface treated layer, the surface treated layer includes a particle having three or more projections, the number of the particles per μm² in the surface treated layer is 0.4 or more, and the surface roughness Rq on the surface treated layer side measured by a laser microscope is 0.5 μm or less.

In one of the embodiments of the surface treated copper foil of the present application, the total deposition amount of Co, Ni, and Mo is 800 μg/dm² or less in the surface treated layer.

In one of the embodiments of the surface treated copper foil of the present application, the total deposition amount of Co, Ni, and Mo is 600 μg/dm² or less in the surface treated layer.

In another one of the embodiments of the surface treated copper foil of the present application, the deposition amount of Co is 400 μg/dm² or less in the surface treated layer.

In another one of the embodiments of the surface treated copper foil of the present application, the deposition amount of Co is 320 μg/dm² or less in the surface treated layer.

In another one of the embodiments of the surface treated copper foil of the present application, the deposition amount of Co is 240 μg/dm² or less in the surface treated layer.

In another one of the embodiments of the surface treated copper foil of the present application, the deposition amount of Ni is 600 μg/dm² or less in the surface treated layer.

In another one of the embodiments of the surface treated copper foil of the present application, the deposition amount of Ni is 480 μg/dm² or less in the surface treated layer.

In another one of the embodiments of the surface treated copper foil of the present application, the deposition amount of Ni is 360 μg/dm² or less in the surface treated layer.

In another one of the embodiments of the surface treated copper foil of the present application, the deposition amount of Mo is 600 μg/dm² or less in the surface treated layer.

In another one of the embodiments of the surface treated copper foil of the present application, the deposition amount of Mo is 480 μg/dm² or less in the surface treated layer.

In another one of the embodiments of the surface treated copper foil of the present application, the deposition amount of Mo is 360 μg/dm² or less in the surface treated layer.

In another one of the embodiments of the surface treated copper foil of the present application, the surface treated layer includes a roughened layer.

In another one of the embodiments of the surface treated copper foil of the present application, a resin layer is provided on the surface treated layer.

In another one of the embodiments of the surface treated copper foil of the present application, the resin layer includes a dielectric.

In another one of the embodiments of the surface treated copper foil of the present application, the surface treated copper foil is used for a high frequency circuit board of 1 GHz or higher.

Another aspect of one or more embodiments of the present application is a carrier-attached copper foil including a carrier, an intermediate layer, and an ultra-thin copper layer in this order, and the ultra-thin copper layer is the surface treated copper foil according to one or more embodiments of the present application.

In one of the embodiments of the carrier-attached copper foil of the present application, the ultra-thin copper layer is provided on two sides of the carrier.

In another one of the embodiments of the carrier attached copper foil of the present application, the carrier has a roughened layer on a surface of a side opposite to a side facing the ultra-thin copper layer.

Another aspect of one or more embodiments of the present application is a laminate including the surface treated copper foil according to one or more embodiments of the present application or the carrier-attached copper foil according to one or more embodiments of the present application, and a resin substrate.

Another aspect of one or more embodiments of the present application is a manufacturing method of a printed wiring board using the surface treated copper foil according to one or more embodiments of the present application or the carrier-attached copper foil according to one or more embodiments of the present application.

Another aspect of one or more embodiments of the present application is a method for manufacturing an electronic device using a printed wiring board manufactured by the method according to one or more embodiments of the present application.

Another aspect of one or more embodiments of the present application is a manufacturing method of a printed wiring board including a step of preparing the carrier-attached copper foil according to one or more embodiments of the present application and an insulating substrate, a step of laminating the carrier-attached copper foil and the insulating substrate, a step of forming a copper-clad laminate by removing a carrier of the carrier-attached copper foil after laminating the carrier-attached copper foil and the insulating substrate, and a step of forming a circuit by means of any one selected from a semi-additive method, a subtractive method, a partly-additive method, and a modified semi-additive method.

Another aspect of one or more embodiments of the present application is a manufacturing method of a printed wiring board including a step of forming a circuit on a surface on the ultra-thin copper layer side or a surface on the carrier side of the carrier-attached copper foil according to one or more embodiments of the present application, a step of forming a resin layer on the surface on the ultra-thin copper layer side or the surface on the carrier side of the carrier-attached copper foil so that the circuit is buried, a step of forming a circuit on the resin layer, a step of detaching the carrier or the ultra-thin copper layer after forming the circuit on the resin layer, and a step of exposing the circuit that is formed on the surface on the ultra-thin copper layer side or the surface on the carrier side and is buried in the resin layer as a result of removing the ultra-thin copper layer or the carrier after detaching the carrier or the ultra-thin copper layer.

In one of the embodiments of the manufacturing method of a printed wiring board of the present application, the step of forming a circuit on the resin layer includes a step of attaching another carrier-attached copper foil to an ultra-thin copper foil layer side of the resin layer and a step of forming the circuit by using the carrier-attached copper foil attached to the resin layer.

In another one of the embodiments of the manufacturing method of a printed wiring board of the present application, the carrier-attached copper foil that is attached to the resin layer is the carrier-attached copper foil according to one or more embodiments of the present application.

In another one of the embodiments of the manufacturing method of a printed wiring board of the present application, the step of forming a circuit on the resin layer is performed by means of any one selected from a semi-additive method, a subtractive method, a partly-additive method, and a modified semi-additive method.

In another one of the embodiments of the manufacturing method of a printed wiring board of the present application, the carrier-attached copper foil having a circuit formed on the surface has a substrate or a resin layer on the surface on the carrier side or the surface on the ultra-thin copper layer side of the carrier-attached copper foil.

### Advantageous Effect of Invention

According to one or more embodiments of the present application, it is possible to provide a surface treated copper foil in which the transmission loss is favorably suppressed even when the surface treated copper foil is used in a high frequency circuit board.

### BRIEF DESCRIPTION OF DRAWINGS

FIG. 1 is a photography of microscopic observation of a surface of the surface treated layer in Example 3.

FIG. 2 is a photography of microscopic observation of a surface of the surface treated layer in Comparative Example 2.

FIG. 3 is a diagram for explaining an evaluation of a difference in level.

FIG. 4 is a diagram for explaining an evaluation of an overlapping of particles and a valley.

FIG. 5 is a diagram providing examples of particles.

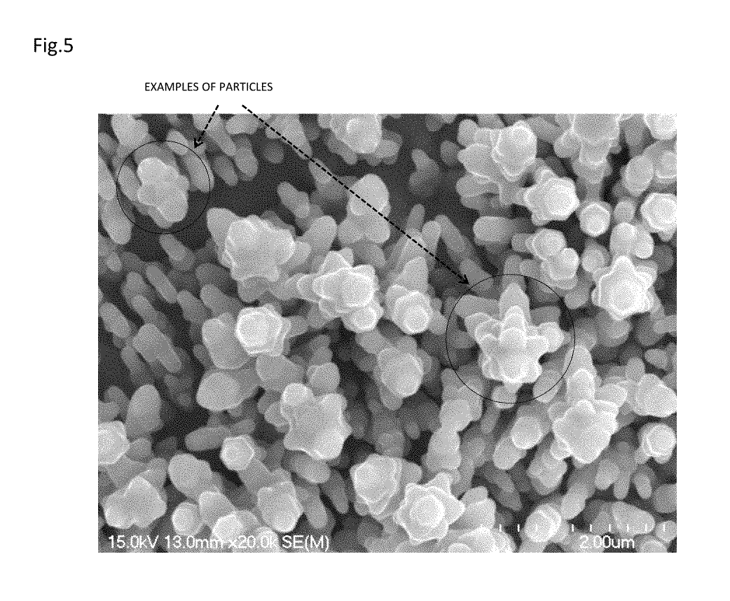

FIG. 6 is a diagram providing an example of a top portion of a particle.

FIG. 7 is a diagram providing an example of a portion of a particle including a portion that is considered to be the highest in the particle and having the difference in level in 70% or more of the circumference (a portion surrounded by a dotted line).

FIG. 8 is a diagram providing an example of a portion of a particle including a portion that is considered to be the highest in the particle and surrounded by the valley (a portion surrounded by a dotted line).

FIG. 9 is a diagram providing an example of a portion of a particle including a portion that is considered to be the highest in the particle and surrounded by the difference in level and valley (a portion surrounded by a dotted line).

FIG. 10 is a diagram for explaining an evaluation of the length of a convex portion of a particle.

FIG. 11 is a diagram providing an example of a particle with a portion being outside the frame of a photograph.

FIG. 12 is a diagram for explaining an evaluation of the width of a convex portion of a particle.

### DESCRIPTION OF EMBODIMENTS

### [Surface Treated Layer]

The surface treated layer according to one or more embodiments of the present application is a surface treated copper foil having a surface treated layer formed on at least one surface, the total deposition amount of Co, Ni, and Mo on the surface treated layer is 1000 μg/dm² or less, and the surface treated layer has particles each having three or more projections.

### [Copper Foil]

The form of the copper foil that can be used for one or more embodiments of the present application is not particularly limited, but is typically in a form of a rolled copper foil or an electrolytic copper foil. In general, an electrolytic copper foil is manufactured by means of copper sulfate plating bath and electrolytic deposition of copper on a titanium or stainless drum, and a rolled copper foil is manufactured by repeating plastic working and heat treatment using a mill roll. A rolled copper foil is more frequently adopted in the use that requires flexibility.

Materials of the copper foil may contain a highly pure copper such as a tough pitch copper, phosphorus deoxidized copper, and an oxygen-free copper that are usually used for a conductor pattern of a printed wiring board, and in addition, a copper containing Sn, a copper containing Ag, and a copper alloy such as a Cr, Zr or Mg-added copper alloy and a Ni and Si-added Corson copper alloy can also be used. Note that when the term “copper foil” is used alone in this specification, the term includes a copper alloy foil. When a copper alloy foil is used as a copper foil for a high-frequency circuit board, the copper alloy foil with electric resistibility that is not markedly higher than copper is preferably used.

It should be noted that the thickness of the copper foil according to one or more embodiments of the present application is not limited, but is typically 0.5-3000 μm, is preferably, 1.0-1000 μm, is preferably 1.0-300 μm, is preferably 1.0-100 μm, is preferably 1.0-75 μm, is preferably 1.0-40 μm, is preferably 1.5-20 μm, is preferably 1.5-15 μm, is preferably 1.5-12 μm, and is preferably 1.5-10 μm.

### [Surface Treated Layer]

A surface treated layer is formed on at least one of the surfaces of the copper foil. The surface treated layer is preferably one or more layers selected from a roughened layer, a rustproofing layer, a heat-resistant layer, and a silane coupling-treated layer. The surface treated layer according to one or more embodiments of the present application may be formed on a surface adhered to a resin (M face), may be formed on a surface (S face) that is on the opposite side of the resin-adhered surface (M face), or may be formed on both of the surfaces.

A roughening treatment can be conducted by forming roughening particles of copper or copper alloy as an example. The roughening treatment may adopt fine particles. In addition, after the roughening treatment, a plating covering treatment may be conducted. A surface treated layer formed by such a roughening treatment, a rustproofing treatment, a heat-resistant treatment, a silane coupling treatment, a treatment to immerse in a treatment solution, or a plating may contain any one or an alloy of at least one selected from a group of Cu, Ni, Fe, Co, Zn, Cr, Mo, W, P, As, Ag, Sn, and Ge, or an organic compound.

When the surface treated layer is formed by using any one of a roughened layer, a rustproofing layer, a heat-resistant layer, and a silane coupling-treated layer, the order of these layers is not particularly limited, but may be, for example, a roughening layer is formed on the copper foil surface, and a Zn metal layer or an alloy treated layer containing Zn may be provided on the roughening layer as a rustproofing/heat-resistant layer. On the Zn metal layer or the alloy treated layer containing Zn, a chromate treated layer may be provided. In addition, a silane coupling-treated layer may be provided on the chromate treated layer.

### [Metal Deposition Amount]

In the surface treated copper foil according to one or more embodiments of the present application, the total deposition amount of Co, Ni, and Mo is controlled to be 1000 μg/dm² or less in the surface treated layer. In the surface treated copper foil according to one or more embodiments of the present application, the high frequency transmission loss can be reduced because the deposition amount of Co, Ni, and Mo that have relatively high magnetic permeability and relatively low electric conductivity, which cause the transmission loss, is controlled. The total deposition amount of Co, Ni, and Mo in the surface treated layer is preferably 800 μg/dm² or less, is more preferably 600 μg/dm² or less, is furthermore preferably 500 μg/dm² or less, is furthermore preferably 300 μg/dm² or less, and is furthermore preferably 0 μg/dm² (indicating the lower limit of quantitation or less). The surface treated layer may contain one or more element(s) selected from a group of Co, Ni, and Mo. The surface treated layer may also contain two or more elements selected from a group of Co, Ni, and Mo. In addition, the surface treated layer may contain three elements including Co, Ni, and Mo. The surface treated layer may contain Co and Ni. The surface treated layer may contain Co and Mo. The surface treated layer may contain Ni and Mo.

Regarding Co, Ni, and Mo in the surface treated layer, it is preferable to control the deposition amount of each of the elements in terms of the reduction of transmission loss. More specifically, the deposition amount of Co in the surface treated layer is preferably 400 μg/dm² or less, is more preferably 320 μg/dm² or less, is furthermore preferably 240 μg/dm² or less, is furthermore preferably 160 μg/dm² or less, and is furthermore preferably 120 μg/dm² or less. In addition, the deposition amount of Ni in the surface treated layer is preferably 600 μg/dm² or less, is more preferably 480 μg/dm² or less, is furthermore preferably 360 μg/dm² or less, is furthermore preferably 240 μg/dm² or less, and is furthermore preferably 180 μg/dm² or less. The deposition amount of Mo in the surface treated layer is preferably 600 μg/dm² or less, is more preferably 480 μg/dm² or less, is furthermore preferably 360 μg/dm² or less, is furthermore preferably 240 μg/dm² or less, and is furthermore preferably 180 μg/dm² or less.

The surface treated layer has particles each having three or more projections, and the number of such particles per μm² is 0.4 or more. Here, particles refer to a concept including roughening particles formed by the above-described roughening treatment (roughening plating) and/or roughening treatments (roughening plating) described later. With this structure, owing to the anchor effect, after a resin substrate and the surface treated copper foil is laminated, the peel strength can be secured at the time of peeling the surface treated copper foil from the resin substrate while the transmission loss can be favorably suppressed. In addition/alternatively, with this structure, after producing a copper-clad laminate by laminating a resin substrate and the surface treated copper foil and heating the copper-clad laminate, the peel strength can be made favorable at the time of peeling the surface treated copper foil from the resin substrate in room temperature. The above-described particles are preferably formed all over the surface of the copper foil. As a result of the particles formed all over the surface of the copper foil, the peel strength is more favorably improved. In order to improve the peel strength, the surface treated layer preferably has particles each having four or more projections, more preferably has particles each having five or more projections, and furthermore preferably has particles each having six or more projections. Note that as described later, each of the above-described projections is a convex portion of a particle that has the length of 0.050 μm or more and the width of 0.220 μm or less. Because the particles having three or more projections described above readily dig into a resin, when such particles are present in a prescribed number or more, adhesion between a copper foil and the resin can be enhanced.

Furthermore, in view of the improvement of the peel strength, in the surface treated layer, the number of particles having three or more projections per μm² is preferably 0.5 or more, the number of particles having three or more projections per μm² is preferably 0.6 or more, the number of particles having three or more projections per μm² is preferably 0.7 or more, the number of particles having three or more projections per μm² is preferably 0.8 or more, the number of particles having three or more projections per μm² is preferably 0.9 or more, the number of particles having three or more projections per μm² is preferably 1.0 or more, the number of particles having three or more projections per μm² is preferably 1.1 or more, the number of particles having three or more projections per μm² is preferably 1.2 or more, and the number of particles having three or more projections per μm² is preferably 1.3 or more. The upper limit of the number of particles having three or more projections is not necessarily limited in particular, but for example, the upper limit of the number of particles per μm² is typically 50.0 or less, 40.0 or less, 30.0 or less, 20.0 or less, 15.0 or less, 10.0 or less, and 5.0 or less.

### [Surface Roughness Rz]

The roughness of a surface treated copper foil surface is a key factor of the conductor loss, and the transmission loss is reduced as the surface roughness becomes smaller. In view of this point, it is preferable that the surface roughness Rz measured by a contact type roughness meter is controlled to be 1.3 μm or less on the surface treated layer side of the surface treated copper foil according to one or more embodiments of the present application. With this structure, the transmission loss can be favorably reduced. The surface roughness Rz measured by a contact type roughness meter on the surface treated layer side of the surface treated copper foil according to one or more embodiments of the present application is preferably controlled to be 1.30 μm or less, is preferably controlled to be 1.2 μm or less, is more preferably controlled to be 1.1 μm or less, is more preferably controlled to be 1.10 μm or less, is preferably controlled to be 1.0 μm or less, and is more preferably controlled to be 1.00 μm or less. It is also preferable that the surface roughness Rz of both surfaces is controlled to be 1.3 μm or less. With this structure, the high frequency transmission loss can be more favorably reduced. The surface roughness Rz of both surfaces is more preferably 1.30 μm or less, is more preferably 1.2 μm or less, is furthermore preferably 1.1 μm or less, is furthermore preferably 1.10 μm or less, is furthermore preferably 1.0 μm or less, and is furthermore preferably 1.00 μm or less. The lower limit of the surface roughness Rz of the surface treated layer side measured by a contact type roughness meter is not necessarily limited in particular, but is typically 0.01 μm or more, or specifically, 0.02 μm or more as an example. In view of further improving the adhesion between the surface treated copper foil and the resin, the surface roughness Rz on the surface treated layer side measured by a contact type roughness meter is preferably 0.60 μm or more, is preferably 0.65 μm or more, is preferably 0.70 μm or more, is preferably 0.75 μm or more, is preferably 0.80 μm or more, is preferably 0.85 μm or more, and is preferably 0.89 μm or more.

### [Maximum Profile Peak Height Rp]

It is preferable that the surface roughness Rp measured by a laser microscope is controlled to be 1.59 μm or less on the surface treated layer side of the surface treated copper foil according to one or more embodiments of the present application, because the transmission loss can be favorably reduced under such a condition. The surface roughness Rp of the surface treated layer side measured by a laser microscope is preferably 1.49 μm or less, is more preferably 1.39 μm or less, is more preferably 1.29 μm or less, and is more preferably 1.09 μm or less. The lower limit of the surface roughness Rp of the surface treated layer side measured by a laser microscope is not necessarily limited in particular, but is typically 0.01 μm or more, or more specifically 0.02 μm or more as an example. In view of further improving the adhesion between the surface treated copper foil and the resin, the surface roughness Rp on the surface treated layer side measured by a laser microscope is preferably 0.70 μm or more, is preferably 0.75 μm or more, and is preferably 0.80 μm or more.

### [Maximum Profile Valley Depth Rv]

It is preferable that the surface roughness Rv measured by a laser microscope is controlled to be 1.75 μm or less on the surface treated layer side of the surface treated copper foil according to one or more embodiments of the present application, because the transmission loss can be favorably reduced under such a condition. The surface roughness Rv of the surface treated layer side measured by a laser microscope is preferably 1.65 μm or less, is more preferably 1.55 μm or less, is more preferably 1.50 μm or less, is more preferably 1.45 μm or less, and is more preferably 1.30 μm or less. The lower limit of the surface roughness Rv of the surface treated layer side measured by a laser microscope is not necessarily limited in particular, but is typically 0.01 μm or more, or specifically, 0.02 μm or more as an example. In view of further improving the adhesion between the surface treated copper foil and the resin, the surface roughness Rv on the surface treated layer side measured by a laser microscope is preferably 0.98 μm or more.

### [Surface Roughness Rzjis]

The roughness of a copper foil surface is a key factor of the conductor loss, and the transmission loss is reduced as the surface roughness becomes smaller. In view of this point, in the surface treated copper foil according to one or more embodiments of the present application, it is preferable that the surface roughness Rzjis of the surface treated layer side measured by a laser microscope is controlled to be 3.3 μm or less. With this structure, the transmission loss can be favorably reduced. In the surface treated copper foil according to one or more embodiments of the present application, the surface roughness Rzjis of the surface treated layer side measured by a laser microscope is preferably controlled to be 3.30 μm or less, is preferably controlled to be 3.2 μm or less, is more preferably controlled to be 3.1 μm or less, is more preferably controlled to be 3.0 μm or less, is preferably controlled to be 2.20 μm or less, and is preferably controlled to be 2.10 μm or less. The lower limit of the surface roughness Rzjis of the surface treated layer side measured by a laser microscope is not necessarily limited in particular, but is typically 0.01 μm or more, or specifically, 0.02 μm or more as an example. In view of further improving the adhesion between the surface treated copper foil and the resin, the surface roughness Rzjis on the surface treated layer side measured by a laser microscope is preferably 1.00 μm or more, is preferably 1.10 μm or more, is preferably 1.20 μm or more, is preferably 1.30 μm or more, is preferably 1.40 μm or more, is preferably 1.50 μm or more, is preferably 1.60 μm or more, and is preferably 1.70 μm or more.

### [Mean Height of Profile Element Rc]

It is preferable that the surface roughness Rc measured by a laser microscope is controlled to be 1.0 μm or less on the surface treated layer side of the surface treated copper foil according to one or more embodiments of the present application, because the transmission loss can be favorably reduced under such a condition. The surface roughness Rc of the surface treated layer side measured by a laser microscope is preferably 1.00 μm or less, is preferably 0.9 μm or less, is preferably 0.90 μm or less, is preferably 0.85 μm or less, is more preferably 0.8 μm or less, is more preferably 0.7 μm or less and is more preferably 0.70 μm or less. The lower limit of the surface roughness Rc of the surface treated layer side measured by a laser microscope is not necessarily limited in particular, but is typically 0.01 μm or more, or specifically, 0.02 μm or more as an example. In view of further improving the adhesion between the surface treated copper foil and the resin, the surface roughness Rc on the surface treated layer side measured by a laser microscope is preferably 0.50 μm or more, is preferably 0.55 μm or more, and is preferably 0.60 μm or more.

### [Arithmetical Mean Height Ra]

It is preferable that the surface roughness Ra measured by a laser microscope is controlled to be 0.4 μm or less on the surface treated layer side of the surface treated copper foil according to one or more embodiments of the present application, because the transmission loss can be favorably reduced under such a condition. The surface roughness Ra of the surface treated layer side measured by a laser microscope is preferably 0.40 μm or less, is preferably 0.39 μm or less, is more preferably 0.38 μm or less, is more preferably 0.37 μm or less, is more preferably 0.30 μm or less, is more preferably 0.28 μm or less, is more preferably 0.26 μm or less, is more preferably 0.24 μm or less, is more preferably 0.23 μm or less, and is more preferably 0.22 μm or less. The lower limit of the surface roughness Ra of the surface treated layer side measured by a laser microscope is not necessarily limited in particular, but is typically 0.01 μm or more, or specifically, 0.02 μm or more as an example. In view of further improving the adhesion between the surface treated copper foil and the resin, the surface roughness Ra on the surface treated layer side measured by a laser microscope is preferably 0.20 μm or more, and is preferably 0.21 μm or more.

### [Root Mean Square Height Rq]

It is preferable that the surface roughness Rq measured by a laser microscope is controlled to be 0.5 μm or less on the surface treated layer side of the surface treated copper foil according to one or more embodiments of the present application, because the transmission loss can be favorably reduced under such a condition. The surface roughness Rq of the surface treated layer side measured by a laser microscope is preferably 0.50 μm or less, is more preferably 0.49 μm or less, is more preferably 0.48 μm or less, is more preferably 0.47 μm or less, is more preferably 0.34 μm or less, and is more preferably 0.33 μm or less. The lower limit of the surface roughness Rq of the surface treated layer side measured by a contact type roughness meter is not necessarily limited in particular, but is typically 0.01 μm or more, or specifically, 0.02 μm or more as an example. In view of further improving the adhesion between the surface treated copper foil and the resin, the surface roughness Rq on the surface treated layer side measured by a laser microscope is preferably 0.25 μm or more, is preferably 0.26 μm or more, is preferably 0.27 μm or more, is preferably 0.28 μm or more, is preferably 0.29 μm or more, and is preferably 0.30 μm or more.

### [Method for Manufacturing Surface Treated Copper Foil]

In one or more embodiments of the present application, it is preferable that on one or both of surfaces of a copper foil (a rolled copper foil or an electrolytic copper foil), a roughening treatment that makes knob-shaped electrodeposits on the surface of a copper foil without being pickled or the surface of a pickled copper foil is performed. The roughening treatment gives adhesion (peel strength) to a resin (a dielectric). In one or more embodiments of the present application, this roughening treatment can be performed by means of, for example, plating with any one or an alloy of at least one selected from a group of Cu, Ni, Fe, Co, Zn, Cr, Mo, W, P, As, Ag, Sn, and Ge, or a surface treatment with an organic compound. Normal copper plating or other treatments may be performed as a pre-treatment before the roughening, and a plating covering treatment may be performed with the same metal as a surface treatment after the roughening to give heat resistance and chemical resistance. It should be noted that plating with any one or an alloy of at least one selected from a group of Cu, Ni, Fe, Co, Zn, Cr, Mo, W, P, As, Ag, Sn, and Ge may be performed without the roughening treatment. Afterwards, cover plating with the same metal may be performed as a surface treatment to give heat resistance and chemical resistance. An advantage that can be obtained when the roughening treatment is performed is that the strength of adhesion to the resin increases. When the roughening treatment is not performed, the manufacturing process of the surface treated copper foil is simplified, which gives advantageous results of improved productivity, reduced costs, and smaller roughness. By controlling the composition of solution, the current density, and the amount of coulomb of this plating treatment of the surface of a copper foil, in the surface treated layer according to one or more embodiments of the present application, the total deposition amount of Co and Ni, the shape of each particle (each particle having three or more projections) on the surface treated layer, the number of particles having three or more projections, and the surface roughness Rzjis, the surface roughness Rz, the maximum profile peak height Rp, the maximum profile valley depth Rv, the mean height Rc, the arithmetical mean height Ra, and the root mean square height Rq can be controlled.

The surface treatment according to one or more embodiments of the present application is carried out to the surface of the copper foil by applying six-stage plating as a roughening treatment followed by a chromate treatment and a silane coating treatment (silane coupling treatment). Note that a treatment to provide a heat-resistant layer and/or a rust proof layer may be carried out after the above-described roughening treatment and before the chromate treatment.

The conditions of the above-mentioned roughening treatment (six-stage plating: the following plating treatments 1 to 6 are performed in this order) are provided below.

### (Composition of Solution)

Cu: 10-30 g/L

W: 0-50 ppm

Sodium dodecyl sulfate: 0-50 ppm

Sulfuric acid: 10-150 g/L

Solution temperature: 15-60° C.

(Current density, plating time, and amount of coulomb)
Plating treatment 1

current density: 50-120 A/dm², plating time: 1.0-2.0 seconds, amount of coulomb: 70-120 As/dm²
Plating treatment 2

current density: 6-8 A/dm², plating time: 3.1-5.8 seconds, amount of coulomb: 19-35 As/dm²
Plating treatment 3

current density: 50-120 A/dm², plating time: 1.0-2.0 seconds, amount of coulomb: 70-120 As/dm²
Plating treatment 4

current density: 6-8 A/dm², plating time: 3.1-5.8 seconds, amount of coulomb: 19-35 As/dm²
Plating treatment 5

current density: 6-8 A/dm², plating time: 3.1-5.8 seconds, amount of coulomb: 19-35 As/dm²
Plating treatment 6

current density: 6-8 A/dm², plating time: 3.1-5.8 seconds, amount of coulomb: 19-35 As/dm²

The composition of solution used in the above-mentioned chromate treatment and the conditions of the treatment are provided below.

K₂Cr₂O₇: 1-10 g/L

Zn: 0-5 g/L

pH: 2-5

solution temperature: 20-60° C.

current density: 0-3 A/dm²

plating time: 0-3 seconds

The above-mentioned silane coating treatment can be carried out by using a treatment solution containing silane that is known in the art at a concentration of 0.1-10 vol %. Preferably, the silane coating treatment is carried out by shower coating using a treatment solution of 0.1-10 vol % diaminosilane. This diaminosilane can be diaminosilane known in the art.

### [Transmission Loss]

Because signal attenuation is controlled at the time of signal transmission at a high frequency when the transmission loss is small, stable signal transmission can be realized in a circuit that transmits signals at a high frequency. For that reason, a surface treated copper foil with a smaller value of transmission loss is favorable because such a copper foil is suitable for the use as a circuit that transmits signals at high frequency (e.g., a high frequency circuit board for 1GHz or higher frequency signals). After the surface treated copper foil is attached to a commercially available liquid crystal polymer resin (Vecstar CTZ-50 μm manufactured by KURARAY CO., LTD.), a microstrip line is formed by etching in a manner that the characteristic impedance becomes 50Ω, a transmission coefficient is measured by using a network analyzer HP8720C manufactured by HP Inc. and transmission loss is obtained at the frequency of 20 GHz and at the frequency of 40 GHz. At that time, the transmission loss at the frequency of 20 GHz is preferably less than 5.0 dB/10 cm, is more preferably less than 4.1 dB/10 cm, and is furthermore preferably less than 3.7 dB/10 cm.

### [Heat Resistance]

High heat resistance is preferable because adhesion between the surface treated copper foil and resin is not easily degraded under high-temperature environment and therefore the surface treated copper foil can be used under high-temperature environment.

In one or more embodiments of the present application, heat resistance is evaluated by peel strength retention. Normal peel strength and peel strength after heating at 150° C. for 72 hours (3 days), 168 hours (7 days) or 240 hours (10days) are measured by a tensile tester Autograph 100 in accordance with IPC-TM-650 using the surface treated copper foil with the surface on the surface treated side being laminated on a resin substrate (LCP: a liquid crystal polymer resin (a copolymer of hydroxybenzoic acid (ester) and hydroxynaphthoic acid (ester)) film, Vecstar™ CTZ-50 μm thick manufactured by KURARAY CO., LTD.) for the normal peel strength and the laminated surface treated copper foil after being heated at 150° C. for 72 hours (3 days), 168 hours (7 days) or 240 hours (10 days) for the peel strength after heating.

Afterwards, peel strength retention represented by the following equation is calculated.

peel strength retention (%)=peel strength (kg/cm) after heating at 150° C. for 72 hours (3 days), 168 hours (7 days), or 240 hours (10 days)/normal peel strength (kg/cm)×100

This peel strength retention after heating at 150° C. for 168 hours (7 days) is preferably 50% or higher, is more preferably 60% or higher, is furthermore preferably 70% or higher, is furthermore preferably 75% or higher, is furthermore preferably 80% or higher, and is furthermore preferably 85% or higher.

This peel strength retention after heating at 150° C. for 72 hours (3 days) is preferably 50% or higher, is more preferably 60% or higher, is furthermore preferably 70% or higher, is furthermore preferably 75% or higher, is furthermore preferably 80% or higher, and is furthermore preferably 85% or higher.

This peel strength retention after heating at 150° C. for 240 hours (10 days) is preferably 50% or higher, is more preferably 60% or higher, is furthermore preferably 70% or higher, is furthermore preferably 75% or higher, is furthermore preferably 80% or higher, and is furthermore preferably 85% or higher.

### [Carrier-Attached Copper Foil]

The carrier-attached copper foil that is another one of the embodiments of the present application has a carrier, an intermediate layer laminated on the carrier, and an ultra-thin copper layer laminated on the intermediate layer. The ultra-thin copper layer is one of the above-described surface treated copper foils that are the embodiments of the present application. The carrier-attached cooper foil may have the carrier, the intermediate layer, and the ultra-thin copper layer in this order. The carrier-attached copper foil may have a surface treated layer such as a roughened layer on one or both of the surface on the carrier side and the surface on the ultra-thin copper foil side.

When a roughened layer is provided on the surface on the carrier side of the carrier-attached copper foil, an advantage that can be obtained is that at the time of attaching the surface on the carrier side of the carrier-attached copper foil to a support such as a resin substrate to laminate, the carrier and the support such as a resin substrate are not easily detached from each other.

### [Carrier]

The carrier that can be used for one or more embodiments of the present application is typically provided in a form of a metal foil, a resin film, or a sheet of an inorganic substance such as a copper foil, a copper alloy foil, a nickel foil, a nickel alloy foil, an iron foil, an iron alloy foil, a stainless foil, an aluminum foil, an aluminum alloy foil, an insulating resin film (e.g., a polyimide film, a liquid crystal polymer (LCP) film, a polyethylene terephthalate (PET) film, a polyamide film, a polyester film, a fluorine resin film), a ceramic sheet, and a glass sheet.

A copper foil is preferably used as the carrier in one or more embodiments of the present application. This is because the intermediate layer and the ultra-thin copper layer can be easily formed subsequently, owing to high electric conductivity of a copper foil. The carrier is typically provided in a form of a rolled copper foil or an electrolytic copper foil. In general, an electrolytic copper foil is manufactured by copper sulfate plating bath and electrolytic deposition of copper on a titanium or stainless drum, and a rolled copper foil is manufactured by repeating plastic working and heat treatment using a mill roll. Materials of the copper foil may include a highly pure copper such as a tough pitch copper and an oxygen-free copper, and in addition, a copper containing Sn, a copper containing Ag, and a copper alloy such as a Cr, Zr or Mg-added copper alloy and a Ni and Si-added Corson copper alloy can also be used.

The thickness of the carrier that can be used for one or more embodiments of the present application is not particularly limited, but the thickness may be suitably adjusted to serve as a carrier, or may be 12 μm or more as an example. However, because the production cost increases when the carrier is too thick, in general, the preferable thickness is 35 μm or less. Accordingly, the thickness of the carrier is typically 12-70 μm, and is more typically 18-35 μm.

### [Intermediate Layer]

An intermediate layer is provided on the carrier. Another layer(s) may be provided between the carrier and the intermediate layer. The structure of the intermediate layer used in one or more embodiments of the present application is not particularly limited as long as the ultra-thin copper layer is not easily detached from the carrier before a lamination process of the carrier-attached copper foil on an insulating substrate and the ultra-thin copper layer can be detached from the carrier after the laminating process on the insulating substrate. For example, the intermediate layer of the carrier-attached copper foil of one or more embodiments of the present application may contain one element or two or more elements selected from a group consisting of Cr, Ni, Co, Fe, Mo, Ti, W, P, Cu, Al, Zn, an alloy of any of these elements, a hydrate of any of these elements, an oxide of any of these elements and an organic compound. Furthermore, the intermediate layer may be formed of plural layers.

As another example, the intermediate layer can be composed by forming, from the carrier side, a single metal layer formed of a single element selected from a group of elements consisting of Cr, Ni, Co, Fe, Mo, Ti, W, P, Cu, Al and Zn or an alloy layer formed of one element or two or more elements selected from a group of elements consisting of Cr, Ni, Co, Fe, Mo, Ti, W, P, Cu, Al and Zn, and by forming, over the single metal layer or the alloy layer, a layer formed of a hydrate or an oxide of one element or two or more elements selected from the a group of elements consisting of Cr, Ni, Co, Fe, Mo, Ti, W, P, Cu, Al and Zn.

In addition, the organic compound in the intermediate layer may be any known organic compound, and the use of any one of a nitrogen-containing organic compound, a sulfur-containing organic compound, and a carboxylic acid is preferable. As specific examples of the nitrogen-containing organic compound, 1, 2, 3-benzotriazole, carboxy-benzotriazole, N′, N′-bis(benzotriazolyl-methyl) urea, 1H-1, 2, 4-triazole, and 3-amino-1H-1, 2, 4-triazole, which are triazole compounds having a substituent, are preferably used.

As specific examples of the sulfur-containing organic compound, mercaptobenzothiazole, sodium 2-mercaptobenzothiazole, thiocyanuric acid, and 2-benzoimidazole-thiol are preferably used.

As the carboxylic acid, the use of mono-carboxylic acid is particularly preferable, and especially use of oleic acid, linoleic acid, and linoleic acid is preferable.

The intermediate layer can be formed, for example, by laminating, on the carrier, nickel, a nickel-phosphorus alloy or a nickel-cobalt alloy and chromium in this order from the carrier. Since the bonding strength between nickel and copper is higher than the bonding strength between chromium and copper, when the ultra-thin copper layer is detached, the ultra-thin copper layer can be detached at the interface between the ultra-thin copper layer and the chromium. The nickel contained in the intermediate layer is expected to exert a barrier effect that prevents diffusion of a copper component of the carrier into the ultra-thin copper layer. The deposition amount of nickel in the intermediate layer is preferably 100 μg/dm² or more and 40000 μg/dm² or less, is more preferably 100 μg/dm² or more and 4000 μg/dm² or less, is more preferably 100 μg/dm² or more and 2500 μg/dm² or less, and is more preferably 100 μg/dm² or more and less than 1000 μg/dm². The deposition amount of chromium in the intermediate layer is preferably 5 μg/dm² or more and 100 μg/dm² or less. In the case where the intermediate layer is provided on one of the surfaces of the carrier, it is preferable to provide a rustproofing layer such as a Ni-plated layer on the opposite surface of the carrier.

When the intermediate layer is too thick, the thickness may have some influence on glossiness and the size and the number of roughening particles of the roughened surface of the ultra-thin copper layer after surface treatment. Therefore, the thickness of the intermediate layer on the roughened surface of the ultra-thin copper layer is preferably 1-1000 nm, is preferably 1-500 nm, is preferably 2-200 nm, is preferably 2-100 nm, and is more preferably 3-60 nm. It should be noted that the intermediate layer may be provided on both sides of the carrier.

### [Ultra-Thin Copper Layer]

An ultra-thin copper layer is provided on the intermediate layer. Another layer(s) may be provided between the intermediate layer and the ultra-thin copper layer. In addition, the ultrathin copper layer may be provided on both sides of the carrier. The ultra-thin copper layer that is provided in the carrier is a surface treated copper foil that is one of the embodiments of the present application. The thickness of the ultra-thin copper lays is not limited but is in general thinner than the carrier, e.g., 12 μm or less. The thickness is typically 0.5-12 μm and is more typically 1.5-5 μm. Before an ultra-thin copper layer is provided on the intermediate layer, strike plating with a copper-phosphorus alloy may be applied in order to reduce the number of pinholes in the ultra-thin copper layer. As an example, a copper pyrophosphate plating liquid may be used for the strike plating.

The ultra-thin copper layer in the present application is formed under the following conditions.

electrolyte composition

copper: 80-120 g/L

sulfuric acid: 80-120 g/L

chloride: 30-100 ppm

leveling agent 1 (bis(3-sulfopropyl)disulfide): 10-30 ppm

leveling agent 2 (amine compound): 10-30 ppm

Note that as the above amine compound, the following amine compound can be used.

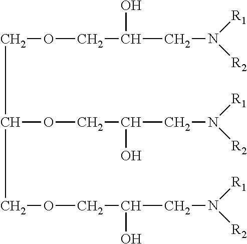

(where R₁ and R₂ each are selected from a group consisting of a hydroxyalkyl group, an ether group, an aryl group, an aromatic-substituted alkyl group, an unsaturated hydrocarbon group and an alkyl group)

### Manufacturing Conditions

current density: 70-100 A/dm²

temperature of electrolyte: 50-65° C.

electrolyte linear flow rate: 1.5-5 m/sec.

electrolysis time: 0.5-10 minutes (adjusted on the basis of the thickness of copper to be deposited and the current density)

### [Resin Layer on Surface Treated Layer]

A resin layer may be provided on the surface treated layer of the surface treated copper foil according to one or more embodiments of the present application. The resin layer may be an insulating resin layer. The resin layer may be an adhesive or may be an insulating resin layer in a semi-cured state (B-stage), serving as an adhesive. The semi-cured state (B-stage) includes a state where the surface thereof is not sticky when touched by a finger, the insulating resin layers of this state can be stacked and stored, and a curing reaction proceeds when a heating treatment is further applied.

The resin layer may be an adhesive resin, i.e., an adhesive, or may be an insulating resin layer in a semi-cured state (B-stage), serving as an adhesive. The semi-cured state (B-stage) include a state where the surface thereof is not sticky when touched by a finger, the insulating resin layers of this state can be stacked and stored, and a curing reaction proceeds when a heating treatment is further applied.

The resin layer may contain a thermosetting resin, or may be a thermoplastic resin. In addition, the resin layer may contain a thermoplastic resin. The resin layer may contain a resin known in the art, a resin curing agent, a compound, a curing accelerator, a dielectric substance, a reaction catalyst, a crosslinking agent, a polymer, a prepreg and a skeletal material. In addition, the resin layer may be formed by using any known forming method or forming device of a resin layer.

The type of resin of the resin layer is not particularly limited but the preferable types of resin include a resin containing at least one selected from the group consisting of an epoxy resin, a polyimide resin, a polyfunctional cyanate compound, a maleimide compound, a polymaleimide compound, a maleimide-base resin, an aromatic maleimide resin, a polyvinyl acetal resin, a urethane resin, polyether sulfone, a polyether sulfone resin, an aromatic polyamide resin, an aromatic polyamide resin polymer, a rubber resin, a polyamine, an aromatic polyamine, a polyamide-imide resin, a rubber modified epoxy resin, a phenoxy resin, a carboxyl group-modified acrylonitrile-butadiene resin, a polyphenylene oxide, a bismaleimide triazine resin, a thermosetting polyphenylene oxide resin, a cyanate resin, an anhydride of a carboxylic acid, an anhydride of a polybasic carboxylic acid, a linear polymer having a crosslinkable functional group, a polyphenylene ether resin, 2,2-bis(4-cyanatophenyl)propane, a phosphorus-containing phenol compound, manganese naphthenate, 2,2-bis(4-glycidylphenyl)propane, a polyphenylene ether-cyanate resin, a siloxane-modified polyamide-imide resin, a cyano ester resin, a phosphazene resin, a rubber-modified polyamide-imide resin, isoprene, a hydrogenated polybutadiene, polyvinyl butyral, phenoxy, a polymer epoxy, an aromatic polyamide, a fluorine resin, a bisphenol, a polyimide block copolymer resin and a cyano ester resin.

Any epoxy resin can be used without problems as long as the epoxy resin has two or more epoxy groups in a molecule and can be used as an electrical/electronic material. A preferable epoxy resin is an epoxy resin obtained by epoxidating a compound having two or more glycidyl groups in a molecule. The epoxy resin that can also be used is one resin or a mixture of two or more resins selected from the group consisting of a bisphenol A type epoxy resin, a bisphenol F type epoxy resin, a bisphenol S type epoxy resin, a bisphenol AD type epoxy resin, a novolak type epoxy resin, a cresol novolak type epoxy resin, an alicyclic epoxy resin, a brominated epoxy resin, a phenol novolak type epoxy resin, a naphthalene type epoxy resin, a brominated bisphenol A type epoxy resin, an o-cresol novolak type epoxy resin, a rubber-modified bisphenol A type epoxy resin, a glycidyl amine type epoxy resin, triglycidyl isocyanurate, a glycidyl amine compound such as an N,N-diglycidylaniline, a glycidyl ester compound such as tetrahydrophthalic acid diglycidyl ester, a phosphorus-containing epoxy resin, a biphenyl type epoxy resin, a biphenyl novolak type epoxy resin, a trishydroxyphenylmethane type epoxy resin and a tetraphenyl ethane type epoxy resin. The epoxy resins in the above group may also be hydrogenated or halogenated for use.

Any phosphorus-containing epoxy resin known in the art can be used as the phosphorus-containing epoxy resin. The phosphorus-containing epoxy resin is preferably an epoxy resin obtained as a derivative of 9, 10-dihydro-9-oxa-10-phospha-phenanthrene-10-oxide that has two or more epoxy groups in a molecule as an example.

The resin and/or the resin composition and/or the compound in the above resin layer is/are dissolved in a solvent such as methyl ethyl ketone (MEK), cyclopentanone, dimethylformamide, dimethylacetamide, N-methylpyrrolidone, toluene, methanol, ethanol, propylene glycol monomethyl ether, cyclohexanone, ethyl cellosolve, N-methyl-2-pyrrolidone, N,N-dimethylacetamide, and N,N-dimethylformamide to obtain a resin liquid (resin varnish), and the resin liquid is applied to the surface treated surface of the surface treated copper foil by using a roll coater method as an example and is dried by heating, if necessary, to remove the solvent to let the resin be in the B-stage. In the drying operation, for example a hot-air drying furnace may be used. The drying temperature may be 100 to 250° C. and preferably 130 to 200° C. The composition of the resin layer may be dissolved by using a solvent to make a resin liquid of 3 to 70 wt %, preferably 3 to 60 wt %, preferably 10 to 40 wt %, more preferably 25 to 40 wt % based on resin solid content. It should be noted that at the time of dissolving the resin and/or the resin composition and/or the compound, the use of a combined solvent of methyl ethyl ketone and cyclopentanone is environmentally the most preferred at the present stage. Note that the use of a solvent having a boiling point ranging from 50 ° C. to 200° C. is preferable.

In addition, the resin layer is preferably a semi-cured resin film of a resin flow ranging from 5% to 35% when the resin flow is measured in accordance with MIL-P-13949G in the MIL standard. In the specification of the present application, the resin flow is a value calculated on the basis of Formula 1 by using a result of taking four 10-cm square samples from a resin-attached surface treated copper foil having a resin of 55-μm thick, stacking the four samples in layers (laminate), attaching to one another by pressing under such conditions that the pressing temperature is 171° C., the pressing force is 14 kgf/cm², and the pressing time is 10 minutes, and measuring the weight of resin outflow at that time, as specified in MIL-P-13949G in the MIL standard.

Resin flow (%)=weight of resin outflow/(weight of laminate)−(weight of copper foil)×100 [Formula 1]

The surface treated copper foil having a resin layer (resin-attached surface treated copper foil) is used in such a form that after the resin layer is laminated on a base material, the entire construct is subjected to thermocompression to thermally cure the resin layer, when the surface treated copper foil is an ultra-thin copper layer of the carrier-attached copper foil, the carrier is detached to expose the ultra-thin copper layer (naturally, the surface of the ultra-thin copper layer on the intermediate layer side is exposed), and a predetermined wiring pattern is formed on the surface opposite to the roughened side of the surface treated copper foil.

When the resin-attached carrier-attached copper foil is used, the number of prepreg material used during manufacturing of a multilayer printed wiring board can be reduced. In addition, the thickness of the resin layer is controlled such that interlayer insulation can be ensured and a copper-clad laminate can be produced even if a prepreg material is not used at all. At this time, the surface of the substrate may be undercoated with an insulating resin to allow further improvement of smoothness on the surface.

Note that the case in which a prepreg material is not used is economically advantageous because the cost for a prepreg material can be saved and the laminating step is simplified. In addition, another advantage is that the thickness of the manufactured multilayer printed circuit board can be reduced as much as the thickness of the prepreg material is reduced, and as a result, an ultra-thin multilayer printed wiring board with a thickness of one layer being 100 μm or less can be manufactured.

The thickness of the resin layer is preferably 0.1 to 120 μm.

When the thickness of the resin layer is thinner than 0.1 μm, bonding strength reduces, and when such a resin-attached copper foil is laminated on a base material having an interlayer material without any prepreg materials interposed between the resin-attached copper foil and the base material, it may become difficult to ensure interlayer insulation with the circuit of the interlayer material. On the other hand, when the thickness of the resin layer is thicker than 120 μm, formation of a resin layer having a desired thickness may become difficult in a single coating step, and therefore an extra material cost and an extra number of steps may be needed, which is economically disadvantageous.

It should be noted that when the surface treated copper foil having a resin layer is used for manufacturing an ultra-thin multilayer printed wiring board, the thickness of the resin layer is preferably 0.1-5 μm, is more preferably 0.5-5 μm, and is more preferably 1-5 μm for the purpose of reducing the thickness of the multilayer printed wiring board.

When the resin layer contains any dielectric, the thickness of the resin layer is preferably 0.1-50 μm, is preferably 0.5-25 μm, and is more preferably 1.0-15 μm.

In addition, the total thickness of the cured resin layer and the semi-cured resin layer is preferably 0.1 to 120 μm, is preferably 5 to 120 μm, is preferably 10 to 120 μm, and is more preferably 10 to 60 μm. The thickness of the cured resin layer is preferably 2 to 30 μm, is preferably 3 to 30 μm, and is more preferably 5 to 20 μm. The thickness of the semi-cured resin layer is preferably 3 to 55 μm, is preferably 7 to 55 μm, and is more preferably 15 to 115 μm. When the total thickness of the resin layers is thicker than 120 μm, manufacturing of a thin multilayer printed wiring board may become difficult, and when the total thickness is thinner than 5 μm, although manufacturing of a thin multilayer printed wiring board may be facilitated, the resin layer that is an insulating layer between circuits in the interlayer becomes too thin that tends to make the insulation between circuits in the interlayer unstable. When the thickness of the cured resin layer is thinner than 2 μm, the surface roughness of the roughened surface of the surface treated copper foil may need to be considered. On the other hand, when the thickness of the cured resin layer exceeds 20 μm, the effect of the cured resin layer may not be notably enhanced, and therefore the total thickness of the insulating layer becomes thicker.

It should be noted that when the thickness of the resin layer is 0.1 to 5 μm, it is preferable that after a heat-resistant layer and/or a rustproofing layer and/or a weather-resistant layer is provided on the roughened surface of the surface treated copper foil, a resin layer is formed on the heat-resistant layer and/or the rustproofing layer and/or the weather-resistant layer in order to enhance the adhesion between the resin layer and the surface treated copper foil.

It should be noted that the thickness of the above-described resin layer is an average value of the thickness measured at any 10 sites of the resin layer by the cross-sectional observation.

Furthermore, when this resin-attacked surface treated copper foil is an ultra-thin copper layer of a carrier-attached copper foil, a carrier-free resin-attached ultra-thin copper layer (surface treated copper foil) can be manufactured as another product form by providing a resin layer on the roughened surface of the ultra-thin copper layer (surface treated copper foil), making the resin layer be in a semi-cured state, and detaching the carrier.

In the following description, some examples of manufacturing steps of a printed wiring board by using the carrier-attached copper foil according to one or more embodiments of the present application.

One of the embodiments of the method for manufacturing a printed wiring board of the present application includes a step of preparing the carrier-attached copper foil according to one or more embodiments of the present application and an insulating substrate, a step of laminating the carrier-attached copper foil and the insulating substrate, a step of detaching the carrier from the carrier-attached copper foil after the carrier-attached copper foil and the insulating substrate are laminated in a manner that the ultra-thin copper layer side faces the insulating substrate in order to form a copper-clad laminate, and a step of forming a circuit by any one of a semi-additive method, a modified semi-additive method, a partly additive method, and a subtractive method. The insulating substrate can be an insulating substrate having an interlayer circuit(s).

In one or more embodiments of the present application, the semi-additive method is a method of forming a conductive pattern by applying non-electrolytic plating onto an insulating substrate or a copper foil seed layer to form a thin plating layer, forming a pattern, and thereafter applying electroplating and etching.

Accordingly, one of the embodiments of the method for manufacturing a printed wiring board of the present application using the semi-additive method includes

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of completely removing an ultra-thin copper layer exposed by detaching the carrier by an etching method using a corrosive solution such as an acid, a plasma method etc.,

a step of forming through-holes or/and blind vias in the resin exposed by removing the ultra-thin copper layer by etching,

a step of applying a desmear treatment to a region containing the through-holes or/and blind vias,

a step of providing an non-electrolytic plating layer on the region containing the resin and the through-holes or/and blind vias,

a step of forming a plating resist on the non-electrolytic plating layer,

a step of applying light to the plating resist and thereafter removing the plating resist of a region in which the circuit is to be formed,

a step of forming an electrolytic plating layer on the region in which a circuit is to be formed and the plating resist has been removed

a step of removing the plating resist; and

a step of removing the non-electrolytic plating layer present in the region other than the region in which a circuit is to be formed by flash etching etc.

Another embodiment of the method for manufacturing a printed wiring board of the present application using the semi-additive method include

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of completely removing an ultra-thin copper layer exposed by detaching the carrier by an etching method using a corrosive solution such as an acid, a plasma method etc.,

a step of forming a non-electrolytic plating layer on the surface of the resin exposed by removing the ultra-thin copper layer by etching,

a step of forming a plating resist on the non-electrolytic plating layer,

a step of applying light to the plating resist, and thereafter removing the plating resist of a region in which the circuit is to be formed,

a step of forming an electrolytic plating layer on the region in which a circuit is to be formed and the plating resist has been removed,

a step of removing the plating resist, and

a step of removing the non-electrolytic plating layer and the ultra-thin copper layer present in the region other than the region in which a circuit is to be formed by flash etching etc.

In one or more embodiments of the present application, the modified semi-additive method is a method of forming a circuit on an insulating layer by laminating a metal foil on an insulating layer, protecting a non-circuit forming portion with a plating resist, thickening a circuit forming portion with copper by electrolytic plating, removing the resist and removing the metal foil of the region other than the circuit forming portion by (flash) etching.

Accordingly, one of the embodiments of the method for manufacturing a printed wiring board of the present application using the modified semi-additive method includes

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of forming through-holes or/and blind vias in the ultra-thin copper layer exposed by detaching the carrier and in the insulating substrate,

a step of applying a desmear treatment to a region containing the through-holes or/and blind vias,

a step of providing an non-electrolytic plating layer on the region containing the through-holes or/and blind vias,

a step of forming a plating resist on the surface of the ultra-thin copper layer exposed by detaching the carrier,

a step of forming a circuit by electroplating after the plating resist is formed,

a step of removing the plating resist, and

a step of removing by flash etching the ultra-thin copper layer exposed by removing the plating resist.

Another embodiment of the method for manufacturing a printed wiring board of the present application using the modified semi-additive method includes

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of forming a plating resist on the ultra-thin copper layer exposed by detaching the carrier,

a step of applying light to the plating resist and thereafter removing the plating resist in a region in which a circuit is to be formed,

a step of forming an electrolytic plating layer on the region in which a circuit is to be formed and the plating resist has been removed,

a step of removing the plating resist, and

a step of removing the non-electrolytic plating layer and the ultra-thin copper layer in the region other than the region in which a circuit is to be formed by flash etching etc.

In one or more embodiments of the present application, the partly additive method is a method of manufacturing a printed wiring board by providing a catalyst nucleus on a substrate having a conductor layer and, if necessary, having holes for through-holes and via holes, forming a conductor circuit by etching, providing a solder resist or a plating resist as needed, and thickening the conductor circuit, and through-hole and via holes, etc. by non-electrolytic plating.

Accordingly, one of the embodiments of the method for manufacturing a printed wiring board of the present application using the partly additive method includes

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of forming through-holes or/and blind vias in the ultra-thin copper layer exposed by detaching the carrier and in the insulating substrate,

a step of applying a desmear treatment to the region containing the through-hole or/and blind vias,

a step of providing a catalyst nucleus to the region containing the through-hole or/and blind vias,

a step of providing an etching resist to the ultra-thin copper layer surface exposed by detaching the carrier,

a step of forming a circuit pattern by applying light to the etching resist,

a step of forming a circuit by removing the ultra-thin copper layer and the catalyst nucleus by an etching method using a corrosive solution such as an acid, a plasma method etc.,

a step of removing the etching resist,

a step of forming a solder resist or a plating resist on the surface of the insulating substrate exposed by removing the ultra-thin copper layer and the catalyst nucleus by an etching method using a corrosive solution such as an acid, a plasma method etc., and

a step of providing a non-electrolytic plating layer in a region in which neither the solder resist nor plating resist is provided.

In one or more embodiments of the present application, the subtractive method is a method of forming a conductive pattern by selectively removing an unnecessary part of the copper foil on a copper-clad laminate by etching etc.

Accordingly, one of the embodiments of the method for manufacturing a printed wiring board of the present application using the subtractive method includes

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of forming through-holes or/and blind vias in the ultra-thin copper layer exposed by detaching the carrier and in the insulating substrate,

a step of applying a desmear treatment to a region containing the through-hole or/and blind vias,

a step of providing an non-electrolytic plating layer in the region containing the through-hole or/and blind vias,

a step of providing an electrolytic plating layer on the surface of the non-electrolytic plating layer,

a step of providing an etching resist on the surface of the electrolytic plating layer or/and the ultra-thin copper layer,

a step of forming a circuit pattern by applying light to the etching resist,

a step of forming a circuit by removing the ultra-thin copper layer, the non-electrolytic plating layer and the electrolytic plating layer by an etching method using a corrosive solution such as an acid, a plasma method, etc., and

a step of removing the etching resist.

Another embodiment of the method for manufacturing a printed wiring board of the present application using the subtractive method includes

a step of preparing a carrier-attached copper foil according to one or more embodiments of the present application and an insulating substrate,

a step of laminating the carrier-attached copper foil and the insulating substrate,

a step of detaching the carrier from the carrier-attached copper foil after the carrier-attached copper foil and the insulating substrate are laminated,

a step of forming through-holes or/and blind vias in the ultra-thin copper layer exposed by detaching the carrier and in the insulating substrate,

a step of applying a desmear treatment to a region containing the through-hole or/and blind vias,

a step of providing an non-electrolytic plating layer on the region containing the through-hole or/and blind vias,

a step of forming a mask on the surface of the non-electrolytic plating layer,

a step of forming an electrolytic plating layer on the surface of the non-electrolytic plating layer in which no mask is formed,

a step of forming an etching resist on the surface of the electrolytic plating layer or/and the ultra-thin copper layer,

a step of forming a circuit pattern by applying light to the etching resist,

a step of forming a circuit by removing the ultra-thin copper layer and the non-electrolytic plating layer by an etching method using a corrosive solution such as an acid, a plasma method, etc., and

a step of removing the etching resist.

The step of forming through-holes or/and blind vias and the following desmear treatment step may not be performed.

In addition, the method for manufacturing a printed wiring board according to one or more embodiments of the present application may be a method for manufacturing a printed wiring board including

a step of forming a circuit on a surface on a side of the ultra-thin copper layer or a surface on a side of the carrier of the carrier-attached copper foil according to one or more embodiments of the present application,

a step of forming a resin layer on the surface on the side of the ultra-thin copper layer or the surface on the side of the carrier of the carrier-attached copper foil so that the circuit is buried,

a step of forming a circuit on the resin layer,

a step of detaching the carrier or the ultra-thin copper layer after forming the circuit on the resin layer, and

a step of exposing, after detaching the carrier or the ultra-thin copper layer, the circuit that is formed on the surface on the side of the ultra-thin copper layer or the surface on the side of the carrier and is buried in the resin layer by removing the carrier or the ultra-thin copper layer.

Now, details of an example of the method for manufacturing a printed wiring board using the carrier-attached copper foil according to one or more embodiments of the present application are described below. Note that an explanation is provided hereafter taking an example of the method for manufacturing using a carrier-attached copper foil that has an ultra-thin copper layer on which a roughened layer is formed. However, the method according to one or more embodiments of the present application is not limited to this method. The following method for manufacturing a printed wiring board can also be performed in the similar manner by using a carrier-attached copper foil having an ultra-thin copper layer on which a roughened layer is not formed.

Step 1: First, a carrier-attached copper foil (first layer) having an ultra-thin copper layer having a roughened layer formed on the surface or a carrier having a roughened layer formed on the surface is prepared.

Step 2: Next, a resist is applied onto the roughened layer on the ultra-thin copper layer or the roughened layer on the carrier, and light exposure and development operation are performed to etch the resist into a predetermined shape.

Step 3: Next, plating for a circuit is formed and thereafter the resist is removed to form a circuit plating having a predetermined shape.

Step 4: Next, a resin layer is laminated by providing an embedding resin on the ultra-thin copper layer or the carrier so as to cover the circuit plating (so as to bury the circuit plating) and subsequently another carrier-attached copper foil (second layer) is bonded from the side of the ultra-thin copper layer or the side of the carrier.

Step 5: Next, the carrier is removed from the second layer carrier-attached copper foil. Note that a copper foil that does not have a carrier may be used for the second layer.

Step 6: Next, holes are formed by applying laser at the predetermined positions of the ultra-thin copper layer of the second layer or the copper foil and the resin layer, and the circuit plating is exposed to form blind vias.

Step 7: Next, blind vias are embedded with copper to form via fill.

Step 8: Next, circuit plating is formed on the via fill and, when necessary, on other portions, as described in Step 2 and Step 3 provided above.

Step 9: Next, the carrier or the ultra-thin copper layer is removed from the first layer carrier-attached copper foil.

Step 10: Next, the ultra-thin copper layer (the copper foil when the copper foil is provided for the second layer, or a carrier when plating for a circuit in the first layer is provided on the roughened layer of the carrier) of both surfaces are removed by flash etching to expose the surface of the circuit plating within the resin layer.

Step 11: Next, bumps are formed on the circuit plating within the resin layer and a copper pillar is formed on the solder. In this manner, a printed-wiring board using the carrier-attached copper foil according to one or more embodiments of the present application is prepared.

The above-described another carrier-attached copper foil (second layer) may be the carrier-attached copper foil according to one or more embodiments of the present application, or may be any existing carrier-attached copper foil, or may be a normal copper foil. In addition, one layer or multiple layers of additional circuit(s) may be formed on the circuit of the second layer, and such circuit(s) may be formed by any one of the semi-additive method, the subtractive method, the partly additive method and the modified semi-additive method.

Note that as the embedding resin, a resin known in the art and a prepreg can be used. For example, BT (bismaleimide triazine) resin and a prepreg, which is glass cloth impregnated with a BT resin, ABF film and ABF manufactured by Ajinomoto Fine-Techno Co., Inc. can be used. As the embedding resin, the resin layer and/or resin and/or prepreg described in the present specification can be used.

Furthermore, the carrier-attached copper foil used as the first layer may have a substrate or a resin layer on a surface on the carrier side or a surface on the ultra-thin copper layer side of the carrier-attached copper foil. The presence of the substrate or the resin layer is advantageous since the carrier-attached copper foil used as the first layer is supported and wrinkle is rarely formed, with the result that productivity is improved. Note that as the substrate or the resin layer, any substrate or any resin layer may be used as long as it has an effect of supporting the carrier-attached copper foil used as the first layer. Example of the substrate or the resin layer that can be used herein include a carrier, a prepreg and a resin layer as described in the specification of the present application, a carrier, a prepreg, a resin layer, a metal plate, a metal foil, a plate of an inorganic compound, a foil of an inorganic compound, a plate of an organic compound and a foil of an organic compound known in the art.

A laminate can be manufactured by attaching the roughened surface side of the surface treated copper foil according to one or more embodiments of the present application to a resin substrate. The resin substrate is not particularly limited as long as the resin substrate has characteristics that are applicable to a printed wiring board etc., but for a rigid PWB, a paper based phenol resin, a paper based epoxy resin, a synthetic fiber cloth-based epoxy resin, a glass cloth/paper composite based epoxy resin, a glass cloth/non-woven glass cloth composite based epoxy resin and a glass cloth based epoxy resin, etc. can be used and for FPC, a polyester film, a polyimide film, a liquid crystal polymer (LCP) film, a fluororesin film etc. can be used. Note that when a liquid crystal polymer (LCP) film or a fluororesin film is used, the peel strength between the film and a surface treated copper foil becomes lower than the peel strength between a polyimide film and the surface-treated copper foil. For that reason, when a liquid crystal polymer (LCP) film or a fluororesin film is used, after a copper circuit is formed, the copper circuit is covered with a coverlay so that the film and the copper circuit do not easily detach from each other. Therefore detachment of the film from the copper circuit due to the lower peel strength can be prevented.

It should be noted that because a liquid crystal polymer (LCP) film and a fluororesin film has a low value of the dielectric tangent, a copper-clad laminate, a printed wiring board, and a printed circuit board that use the liquid crystal polymer (LCP) film or the fluororesin film and the surface treated copper foil according to one or more embodiments of the present application is suitable for use in a high-frequency circuit (a circuit that transmits signals at high frequencies). In addition, the surface treated copper foil according to one or more embodiments of the present application is suitable for use in a high-frequency circuit because the surface is smooth owing to the small particle size in the roughening treatment and the high glossiness.

A method for attaching the surface treated copper foil according to one or more embodiments of the present application to a resin substrate is, for the rigid PWB, a prepreg is prepared by impregnating a base material such as a glass cloth with a resin and curing the rein so as to be in a semi-cured state. The surface treated copper foil can be attached to the resin substrate by stacking the copper foil so that the roughened side faces the prepreg and applying thermocompression. For FPC, a laminate can be manufactured by attaching a base material such as a polyimide film to the copper foil by means of laminate bonding with an adhesive or without an adhesive but under high temperature and pressure. Alternatively, a laminate can be manufactured by applying, drying, and curing a polyimide precursor.

The laminate according to one or more embodiments of the present application can be used for various types of printed wiring boards (PWB), and the usage is not particularly limited. However, in consideration of the number of the conductor pattern layers, the laminate is applicable to, for example, a one-sided PWB, a two-sided PWB and a multilayered (three or more layers) PWB, and in consideration of the types of the insulating substrate materials, the laminate is applicable to a rigid PWB, a flexible PWB (FPC) and a rigid/flex PWB.

In one or more embodiments of the present application, “printed wiring board” includes a printed wiring board, a printed circuit board, or a printed substrate mounted on a component. In addition, two or more printed wiring boards according to one or more embodiments of the present application can be connected so that a printed wiring board having two or more printed wiring boards connected to each other can be manufactured. Moreover, at least one printed wiring board according to one or more embodiments of the present application and another one printed wiring board according to one or more embodiments of the present application or another printed wiring board that is not the printed wiring board according to one or more embodiments of the present application can be connected, and an electronic device can be manufactured by using these printed wiring boards. Note that in one or more embodiments of the present application, “copper circuit” includes copper wiring. In addition, the printed wiring board according to one or more embodiments of the present application may be connected to a component to manufacture a printed wiring board. Moreover, at least one printed wiring board according to one or more embodiments of the present application and another one printed wiring board according to one or more embodiments of the present application or another printed wiring board that is not the printed wiring board according to one or more embodiments of the present application can be connected, and a printed wiring board having two or more printed wiring boards according to one or more embodiments of the present application connected to each other and a component may be further added to manufacture a printed wiring board having two or more printed wiring boards connected to each other. Here, “component” includes a connecter, LCD (Liquid Crystal Display), an electronic component such as a glass substrate used for LCD, an electronic component including a semiconductor integrated circuit such as IC (Integrated Circuit), LSI (Large Scale Integrated circuit), VLSI (Very Large Scale Integrated circuit), ULSI (Ultra-Large Scale Integration) (e.g., an IC chip, a LSI chip, a VLSI chip, and a ULSI chip), a component to shield an electronic circuit, and a component that is needed to fix a cover etc. on a printed wiring board.

### EXAMPLES

In the following description, an explanation is provided on the basis of Examples and Comparative Examples. Note that Examples in the present specification are merely an example, and therefore one or more embodiments of the present application is/are not limited to Examples. In other words, other forms and modifications of one or more embodiments of the present application are also included. Note that for the original foil used in Examples 1-5 and 8-12 and Comparative Examples 1-3, 7 and 9, an 18-μm-thick rolled copper foil, TPC (tough-pitch copper specified by JIS H3100 C1100 manufactured by JX Nippon Mining & Metals Corporation) was used. For the original foil in Examples 6 and 7 and Comparative Examples 4, 5, 11, and 12, an 18-μm-thick HLP foil (an electrolytic copper foil manufactured by JX Nippon Mining & Metals Corporation) was used. In Comparative Examples 6, 8, and 10, an 18-μm-thick JTC foil (an electrolytic copper foil manufactured by JX Nippon Mining & Metals Corporation) was used.

For the original foil in Examples 13-15, a carrier-attached copper foil manufactured by means of the following method was used.

In Example 15, an 18-μm-thick electrolytic copper foil (JTC foil manufactured by JX Nippon Mining & Metals Corporation) was prepared as a carrier, and in Examples 13 and 14, the above-described 18-μm-thick rolled copper foil, TPC, was prepared as a carrier. Under the following conditions, an intermediate layer was formed on the surface of the carrier, and an ultra-thin copper layer was formed on the surface of the intermediate layer. Note that when the carrier was an electrolytic copper foil, the intermediate layer was formed on a shiny face (S face).

### Example 13

### <Intermediate Layer>

(1) Ni layer (Ni plating)

The carrier was electroplated on a roll-to-roll continuous plating line under the following conditions to form a Ni layer with the deposition amount of 1000 μg/dm². Details of the plating conditions are provided below.

Nickel sulfate: 270-280 g/L

Nickel chloride: 35-45 g/L

Nickel acetate: 10-20 g/L

Boric acid: 30-40 g/L

Gloss agent: Saccharine, butynediol or others

Dodecyl sodium sulfate: 55-75 ppm

pH: 4-6

Bath temperature: 55-65° C.

Current density: 10 A/dm²
(2) Cr layer (electrolytic chromate treatment)

Next, after water-rinsing and pickling the surface of the Ni layer formed in (1), a Cr layer was subsequently deposited on the Ni layer with a deposition amount of 11 μg/dm² by an electrolytic chromate treatment using a roll-to-roll continuous plating line under the following conditions.

Potassium dichromate: 1-10 g/L, Zinc 0 g/L

pH: 7-10

Solution temperature: 40-60° C.

Current density: 2 A/dm²

### <Ultra-Thin Copper Layer>

Next, after water-rinsing and pickling the surface of the Cr layer formed in (2), the electroplating was continued on a roll-to-roll continuous plating line under the following conditions to form a 1.5-μm-thick ultra-thin copper layer on the Cr layer, and consequently, a carrier-attached copper foil was manufactured.

Copper concentration: 90-110 g/L

Sulfuric acid concentration: 90-110 g/L

Chloride ion concentration: 50-90 ppm

Leveling agent 1 (bis(3-sulfopropyl)-disulfide): 10-30 ppm

Leveling agent 2 (amine compound): 10-30 ppm

Note that the following amine compound was used as the leveling agent 2.

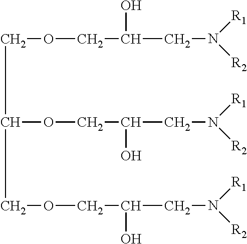

(In the above formula, each of R₁ and R₂ is selected from a group of a hydroxyalkyl group, an ether group, an aryl group, an aromatic-substituted alkyl group, an unsaturated hydrocarbon group, and an alkyl group.)

Temperature of electrolyte: 50-80° C.

Current density: 100 A/dm²

Electrolyte linear flow rate: 1.5-5 m/sec.

### Example 14

### <Intermediate Layer>

(1) Ni—Mo layer (nickel-molybdenum alloy plating)

The carrier was electroplated on a roll-to-roll continuous plating line under the following conditions to form a Ni—Mo layer with the deposition amount of 3000 μg/dm². Details of the plating conditions are provided below.

(Composition of solution) Nickel(II) Sulfate Hexahydrate: 50 g/dm², Sodium molybdate dehydrate: 60 g/dm², sodium citrate: 90 g/dm²

(Solution temperature) 30° C.

(Current density) 1-4 A/dm²

(Plating (current-carrying) time) 3-25 seconds

### <Ultra-Thin Copper Layer>

An ultra-thin copper layer was formed on the Ni—Mo layer formed in (1). The ultra-thin copper layer was formed under the conditions that were the same as the conditions in Example 13 except that the thickness of the ultra-thin copper layer was 2 μm.

### Example 15

### <Intermediate Layer>

(1) Ni layer (Ni plating)

A Ni layer was formed under the conditions that were the same as the conditions in Example 13.
(2) Organic compound layer (organic compound layer forming process)

Next, after water-rinsing and pickling the surface of the Ni layer formed in (1), a solution containing 1-30 g/L concentration of carboxy-benzotriazole (CBTA) at the solution temperature 40° C. and pH 5 was sprayed by showering for 20-120 seconds on the surface of the Ni layer, and consequently, an organic compound layer was formed.

### <Ultra-Thin Copper Layer>

An ultra-thin copper layer was formed on the organic compound layer formed in (2). The ultra-thin copper layer was formed under the conditions that were the same as the conditions in Example 13 except that the thickness of the ultra-thin copper layer was 5 μm.

The surface treated copper foil related to Examples and Comparative Examples can be manufactured by performing a roughening treatment, providing a heat-resistant layer and/or a rustproofing layer as needed, performing a chromate treatment and performing a silane coating treatment (silane coupling treatment) on the surface of the ultra-thin copper layer of the rolled copper foil, the electrolytic copper foil or the carrier-attached copper foil described above within the following range of conditions.

On the surface of the ultra-thin copper layer of the rolled copper foil, the electrolytic copper foil or the carrier-attached copper foil described above the following roughening treatment was performed. Afterwards, the following heat-resistant layer was provided for Examples 4, 5, 7, 9, 10, and 13 and Comparative Examples 4, 5, 10, and 11. The following rustproofing layer was provided for Examples 12 and 15 and Comparative Example 12. Neither the heat-resistant layer nor the rustproofing layer was provided in the other Examples and Comparative Examples. Next, the following chromate treatment was performed. Next to the chromate treatment, the following silane coupling treatment was performed.

It should be noted that when an HLP foil was used as an electrolytic copper foil, a surface treatment such as the above-described roughening treatment was performed on the M face (a deposited face or a face on a side opposite to an electrolytic drum of an electrolytic copper foil manufacturing machine at the time of manufacturing an electrolytic copper foil). When a JTC foil was used as an electrolytic copper foil, a surface treatment such as the above-described roughening treatment was performed on the S face (a shiny face or a face on a side of an electrolytic drum of an electrolytic copper foil manufacturing machine at the time of manufacturing an electrolytic copper foil) of the electrolytic copper foil.

The conditions of the above-mentioned roughening treatment (six-stage plating: the following plating treatments 1 to 6 were performed in this order) are provided below. Note that the current density and the amount of coulomb for each of plating treatments 1 to 6 are provided in Table 1.
Plating treatment 1 and plating treatment 3

(Composition of solution)

Cu: 10-20 g/L

W: 1-5 ppm

Dodecyl sodium sulfate: 1-10 ppm

Sulfuric acid: 70-110 g/L

Solution temperature: 20-30° C.

Current density: 50-110 A/dm²

Plating time: 1.0-2.0 seconds
Plating treatment 2 and plating treatments 4 to 6

(Composition of solution)

Cu: 10-20 g/L

W: 1-5 ppm

Dodecyl sodium sulfate: 1-10 ppm

Sulfuric acid: 70-110 g/L

Solution temperature: 20-30° C.

Current density: 6-8 A/dm²

Plating time: 3.1-5.8 seconds

The conditions of the above-mentioned roughening treatment (six-stage plating: the following plating treatments 1 to 6 were performed in this order) of Example 9 and 15 are provided below. Note that the current density and the amount of coulomb for each of plating treatments 1 to 6 are provided in Table 1.
Plating treatment 1 and plating treatment 3

(Composition of solution) Cu: 15 g/L

W: 3 ppm

Dodecyl sodium sulfate: 5 ppm

Sulfuric acid: 100 g/L

Solution temperature: 25° C.

Plating time: 1.0 seconds (Example 9), 1.2 seconds (Example 15),
Plating treatment 2 and plating treatments 4 to 6

(Composition of solution)

Cu: 15 g/L

W: 3 ppm

Dodecyl sodium sulfate: 5 ppm

Sulfuric acid: 100 g/L

Solution temperature: 25° C.

Plating time: 4.9 seconds (Example 9 Plating treatment 2), 4.8 seconds (Example 9 Plating treatment 4), 5.1 seconds (Example 9 Plating treatment 5), 4.8 seconds (Example 9 Plating treatment 6), 5.0 seconds (Example 15 Plating treatment 2), 4.9 seconds (Example 15 Plating treatment 4), 5.1 seconds (Example 15 Plating treatment 5), 4.8 seconds (Example 15 Plating treatment 6)

In addition, after forming a roughened layer, a heat-resistant layer or a rustproofing layer described below was formed as described in Table 2 provided later in this specification. Note that “Ni—Co plating”, “Co—Mo plating”, “Ni—Mo plating”, and “Co plating” that are written in the “heat-resistant layer” field in Table 2 indicate that Ni—Co plating, Co—Mo plating, Ni—Mo plating and Co plating, respectively, were performed under the conditions provided below. Additionally, in the “heat-resistant layer” field in Table 2, “-” represents that no heat-resistant layer was provided. Moreover, “Zn—Ni plating” in the “rust-proofing layer” filed in Table 2 indicates that Zn—Ni plating was performed under the conditions provided below. In the “rustproofing layer” field in Table 2, “-” represents that no rustproofing layer was provided. Afterwards, a chromate treated layer and a silane coupling-treated layer were provided.
Heat-resistant layer formation process
Ni plating

Composition of solution: nickel 10-40 g/L

pH: 1.0-5.0

Solution temperature: 30-70° C.

Current density: 1-9 A/dm²

Current-applying (plating) time: 0.1-3 seconds

Ni—Co plating

Composition of solution: cobalt 1-20 g/L, nickel 1-20 g/L

pH: 1.5-3.5

Solution temperature: 30-80° C.

Current density: 1-20 A/dm²

Current-applying (plating) time: 0.5-4 seconds
Co plating

Composition of solution: cobalt 10-40 g/L

pH: 1.0-5.0

Solution temperature: 30-70° C.

Current density: 1-9 A/dm²

Current-applying (plating) time: 0.1-3 seconds
Co—Mo plating

Composition of solution: cobalt 1-20 g/L, molybdenum 1-20 g/L

pH: 1.5-3.5

Solution temperature: 30-80° C.

Current density: 1-20 A/dm²

Current-applying (plating) time: 0.5-4 seconds
Ni—Mo plating

Composition of solution: molybdenum 1-20 g/L, nickel 1-20 g/L,

pH: 1.5-3.5

Solution temperature: 30-80° C.

Current density: 1-20 A/dm²

Current-applying (plating) time: 0.5-4 seconds
Rustproofing layer formation process
Zn—Ni plating

Composition of solution: zinc 10-30 g/L, nickel 1-10 g/L

pH: 3-4

Solution temperature: 40-50° C.

Current density: 0.5-5 A/dm²

Current-applying (plating) time: 1-3 seconds

### (Chromate Treatment)

The composition of solution of the treatment solution used in the above-mentioned chromate treatment and the conditions of the treatment are provided below.

K₂Cr₂O₇: 2-7 g/L

Zn: 0.1-1 g/L

pH: 3-4

Solution temperature: 50-60° C.

Current density: 0.5-3 A/dm²

Plating time: 1.5-3.5 seconds

### (Silane Coupling Treatment)

The above-mentioned silane coating treatment (silane coupling treatment) was carried out by shower coating using a treatment solution containing 1.0-2.0 vol % diaminosilane.

The following evaluation was performed on the surface treated layer of each of the manufactured samples and the surface on the side on which each of the samples has the surface treated layer.

### (Metal Deposition Amount)

The deposition amount of each type of metals other than Cu in the surface treated layer was measured by dissolving the coating that was the surface treated layer on the surface of a 50 mm×50 mm copper foil with a solution obtained by mixing HNO₃ (2 wt %) and HCl (5 wt %) (the balance was water) and quantitatively determining the metal concentration in the solution by an ICP emission spectrochemical analyzer (manufactured by SII Nano Technology Inc., SFC-3100) to calculate an amount of metal per unit area (μg/dm²). At that time of the analysis, masking was applied when needed so as not to mix the metal deposition amount of a surface opposite to the surface to be measured, and the analysis was conducted. Note that the measurement was carried out on the samples after the roughening treatment, a treatment to provide a heat-resistant layer, a treatment to provide a rustproof layer, the chromate treatment and the silane coating treatment (silane coupling treatment) described above were performed (i.e., samples after all the surface treatments were performed). It should be noted that when the surface treated layer did not dissolve with the above-described solution of a mixture of HNO₃ (2 wt %) and HCl (5 wt %), the coating that was the surface treated layer might be dissolved with any appropriate solution that could dissolve the coating and thereafter the deposition amount of each type of metals could be measured in the same manner as the method described above.

### (Number of Particles Having Three or More Projections)

On the surface of the surface treated layer of each sample, particles were observed and photographed from directly above (i.e., when the angle of stage on which each sample is mounted is 0° (horizontal)) at 20000-fold magnification and at 15 kV accelerating voltage by using S4700 (a scanning electron microscope) manufactured by Hitachi High-Technologies Corporation, and based on the obtained photographs, the number of particles having three or more projections (the number of particles per μm²) was measured. The number of particles having three or more projections (the number of particles per μm²) was measured in three microscope fields in an area of 6 μm×5 μm, and the average number of particles having three or more projections from the three fields was regarded as the value of the number of particles having three or more projections. Note that the settings such as contrast at the time of observing the photographs may be properly adjusted so as to facilitate the evaluation of differences in level, overlapping of particles, and valleys found in and among the particles that are described later.

Whether the three or more projections were present or absent in a particle was determined as below.

In the above-described photographs, a profile portion of a particle brighter than the surrounding portions was regarded as indicating that the surface of the portion was closer to parallel to the incident direction of the electron beam used for the scanning electron microscope (SEM) observation than the surface of the surrounding portions.

For that reason, the particle profile portion brighter than the surrounding portions was considered to have a surface inclining steeper than the surfaces of the surrounding portion (the surface of the portion was closer to perpendicular to the surface of the copper foil than the surfaces of the surrounding portions). In other words, a portion inside of the particle profile portion brighter than the surrounding portions was considered to be located at a position higher than a portion outside of the particle profile portion brighter than the surrounding portions.

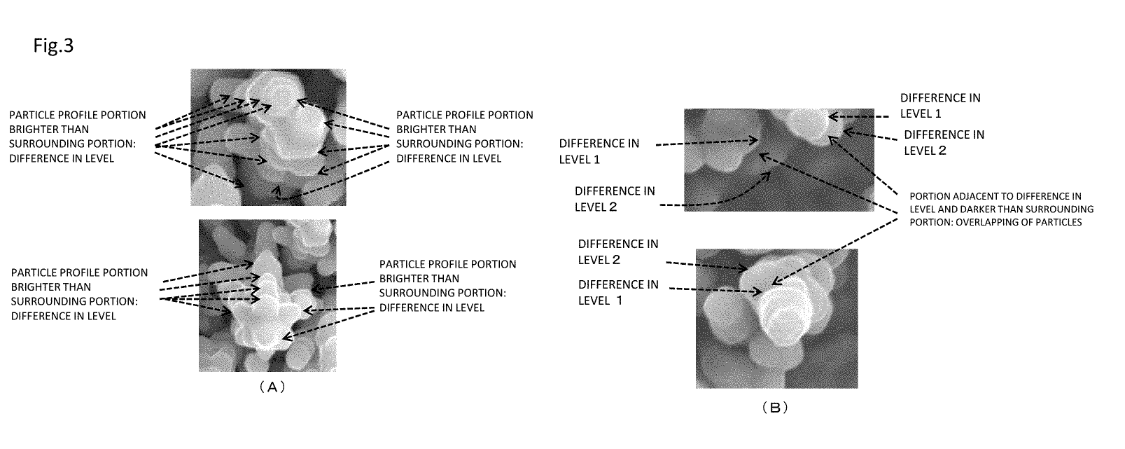

Accordingly, as indicated in FIG. 3(A), the particle profile portion brighter than the surrounding portions was determined to be a difference in level.

A portion darker than the surrounding portions was regarded as indicating a portion located lower than the surrounding portions (valley), or a portion that the electron beams did not thoroughly reach due to overlapping of particles.

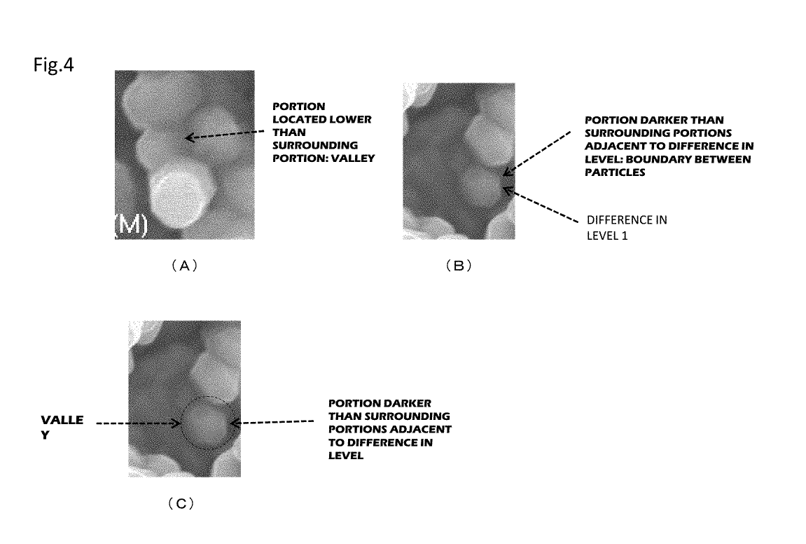

As indicated in FIG. 4(A), among the portions darker than the surrounding portions, a dark portion with the surrounding portions on both sides becoming gradually brighter was determined to be a portion located lower than the surrounding portions, or in other words, a valley. A valley was considered to be a boundary between particles.

As indicated in FIG. 3(B), a portion adjacent to the profile of another particle and darker than the surrounding portions was considered to be a portion which electron beams did not thoroughly reach due to an overhanging profile of a particle. Accordingly, when difference in level 1 was present and difference in level 2 was also present in a portion located lower than difference in level 1, the portion adjacent to the difference in level and darker than the surrounding portions was determined to be overlapping of particles. Additionally, difference in level 2 was also determined to be a portion of a particle. Here, “low(er)” is a concept that includes that the portion is located closer to the copper foil in the perpendicular direction (the thickness direction of the copper foil) than the other portions, or the portion is located closer to a sample stage of a scanning electron microscope in the perpendicular direction (the thickness direction of the copper foil) than the other portions.

As indicated in FIG. 4(B), when difference in level 2 was not observed in a portion lower than difference in level 1, a portion darker than the surrounding portions adjacent to the difference in level was determined to be a boundary between particles.
1. Identification of particle

Each particle was identified as in the following manner.

A portion brighter than the surrounding portions was determined to be a particle because such a portion was a portion higher than the surrounding portions.

A top portion of a particle was counted as one particle.

A portion that appeared higher than the surrounding portions was regarded as the top portion of a particle.

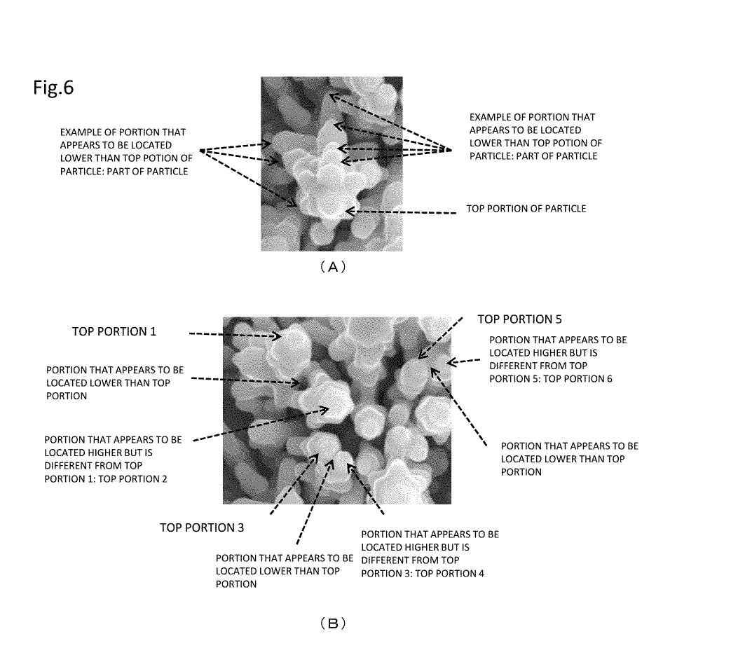

As indicated in FIG. 6(A), a portion that appeared to be located lower than the top portion of a particle (i.e., a portion that appeared to be under the top portion of the particle) was determined to be a part of the particle.

In FIG. 6(B), a portion indicated was adjacent to a portion that appeared to be located lower than the top portion of a particle and the indicated portion appeared to be located higher but was different from the top portion of the particle. Such a portion was considered to be a top portion of another particle and was counted as another particle.

As indicated in FIG. 4(C), a portion surrounded by the above-explained boundaries was determined to be one particle. A particle marked by the dotted line in FIG. 4(C) was surrounded by valleys and a portion darker than the surrounding portions adjacent to a difference in level when difference in level 2 was not observed in a portion lower than difference in level 1.
2. In the above-described photographs, the following measurement was carried out for each particle identified in a manner described in “1. Identification of particle”. A convex portion found on a particle was determined to be a projection when the convex portion had the length of 0.050 μm or more and the width of 0.220 μm or less.
(1) Measurement of length of convex portion of particle
i. In the above-described photographs, a largest possible circle (hereinafter referred to as “largest circle”) that fits within an upper portion of the particle was drawn.

Here, any one of the following portions was regarded as the upper portion of the particle:

(i) a portion of a particle including a portion considered to be the highest in the particle and having the above-described difference in level in 70% or more of the circumference;

(ii) a portion of a particle including a portion considered to be the highest in the particle and surrounded by the above-described valley; and

(iii) a portion of a particle including a portion considered to be the highest in the particle and surrounded by the above-described difference in level and valley.

Here, “high(est)” is a concept that includes that the portion is located farther away from the copper foil in the perpendicular direction (the thickness direction of the copper foil) than the other portions, or the portion is located farther away from a sample stage of a scanning electron microscope in the perpendicular direction (the thickness direction of the copper foil) than the other portions.

In general, when the angle of the surface relative to the incident direction of electron beams is the same, a higher portion (a portion farther away from the sample stage of the SEM) is displayed brighter in SEM photographs. Therefore, when the angle of the surface relative to the incident direction of electron beams is the same, a brighter portion in an SEM photograph is regarded as a higher portion. Similarly, when the angle of the surface relative to the incident direction of electron beams is the same, a darker portion in SEM photographs is regarded as a lower portion. In this manner, whether a portion is located high or low can be determined on the basis of the brightness of an SEM photograph.

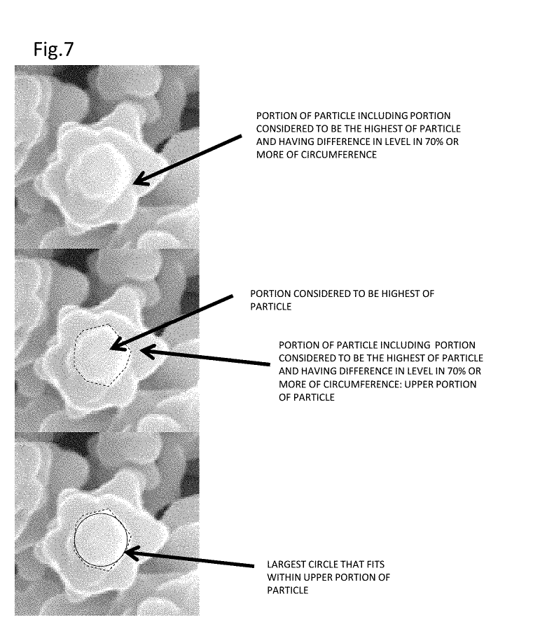

FIG. 7 gives an example of a portion of a particle (surrounded by a dotted line) including a portion considered to be the highest of the particle and having the above-described difference in level in 70% or more of the circumference.

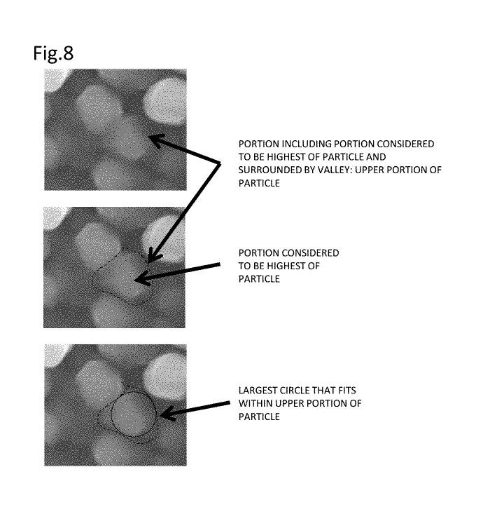

FIG. 8 gives an example of a portion of a particle (surrounded by a dotted line) including a portion considered to be the highest of the particle and surrounded by the above-described valley.

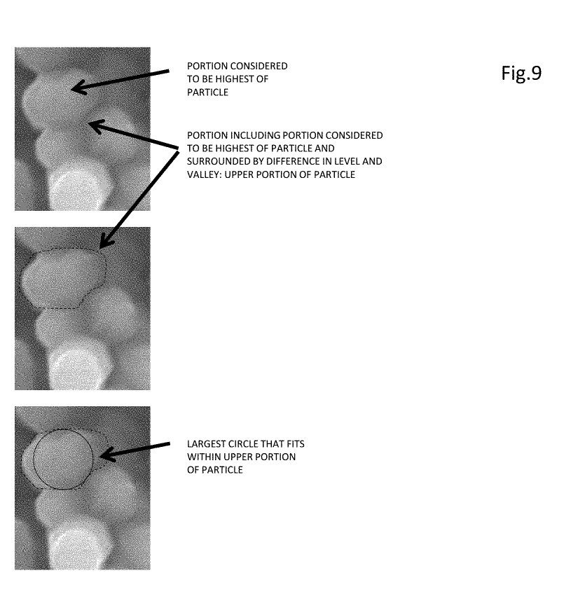

FIG. 9 gives an example of a portion of a particle (surrounded by a dotted line) including a portion considered to be the highest of the particle and surrounded by the above-described difference in level and valley.
ii. In a particle, a portion that did not fit within the largest circle was regarded as a convex portion of the particle. Then, a straight line, line 1, was drawn from the top of the convex portion of the particle to the center of the largest circle. The length of line 1 from the top of the convex portion of the particle to the center of the largest circle was regarded as the length of the convex portion of the particle.

Here, in each of convex portions of a particle, the top of the convex portion of the particle was defined as a point that was farther away from the center of the largest circle than both sides of the top of the convex portion.

When the above-described difference in level was found in a portion surrounded by the above-described difference in level and/or valley and/or overlapping of particles, the difference in level was regarded as one of convex portions of the particle.

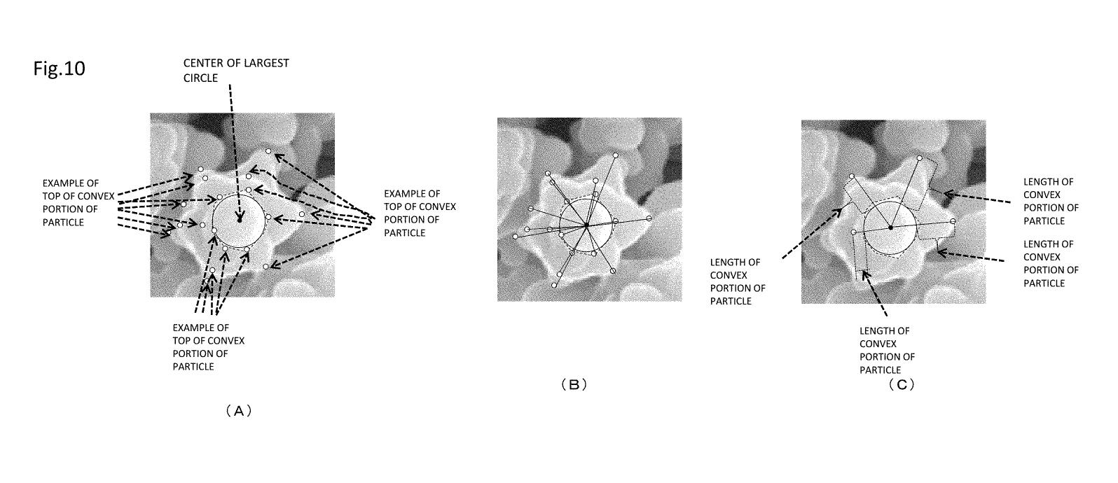

The FIG. 10(A) provides an example of the center of the largest circle indicated by a black circle and the tops of the convex portions of a particle indicated by white circles. Portions outside the largest circle and having the tops of the convex portions were regarded as convex portions of a particle.

FIG. 10(B) is the same photograph as FIG. 10(A) but line 1 is added between the center and each of the tops. A straight line connecting a black circle and a white circle is line 1.

To be more precise, FIG. 10(C) indicates the length of convex portion for some of the convex portions in FIG. 10(B).

Particles having a portion outside the frame of a photograph were also counted.

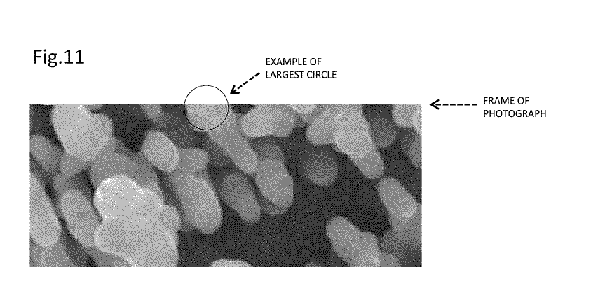

In this case, the largest possible circle was drawn in a manner that a part of the largest possible circle fits within the upper portion inside the frame of the photograph. In other words, a part of the above-described largest circle may be outside the frame of the photograph (FIG. 11).
(2) Measurement of width of convex portion of particle

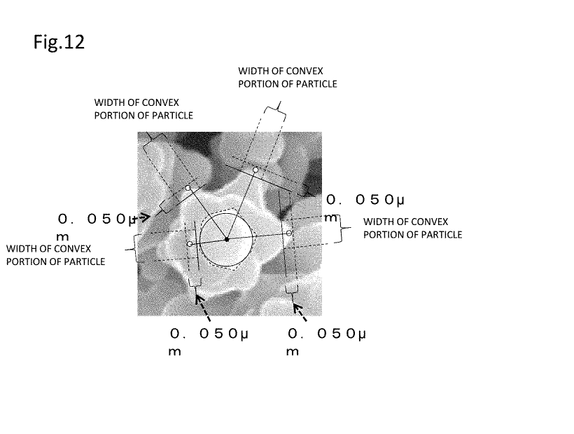

Line 2, a straight line perpendicular to the above-described line 1, was drawn. Line 2 intersected with line 1 at a point located 0.050 μm away from the top of a convex portion of a particle toward the center of the largest circle. The length of a portion of line 2 that overlapped the convex portion of the particle was regarded as the width of the convex portion of the particle. The length of a portion of line 2 that overlapped the convex portion of the particle was the length from a point at which line 2 intersected with the profile of the convex portion of the particle to another point at which line 2 intersected with the profile of the convex portion of the particle. In FIG. 12, a straight line (solid line) intersecting perpendicular to a straight line (line 1) connecting between a white circle and a black circle is line 2.
(3) When the length of a convex portion of a particle was 0.050 μm or more and the width of the convex portion of the particle was 0.220 μm or less, the convex portion of the particle was determined to be a projection. A particle with three or more of the above-defined projections was determined to be “a particle having three or more projections”.

The surface treated layer of the surface treated copper foil in Example 3 had particles having four or more projections, particles having five or more projections, and particles having six or more projections.

### (Peel Strength)

A copper-clad laminate was produced by attaching a side of the surface treated layer of the surface treated copper foil according to each of Examples and Comparative Examples to a resin substrate (LCP: a liquid crystal polymer resin (a copolymer of hydroxybenzoic acid (ester) and hydroxynaphthoic acid (ester)) film, Vecstar™ CTZ-50μm thick manufactured by KURARAY CO., LTD.). The normal peel strength at the time of peeling the surface treated copper foil from the resin substrate and the peel strength at the time of peeling the surface treated copper foil from the resin substrate in room temperature after the copper-clad laminate was heat treated at 150° C. for three days, at 150° C. for seven days, and/or at 150° C. for ten days were measured by peeling the surface treated copper foil from the resin substrate at an angle of 90°. In the measurement of the peel strength, the circuit width was 3 mm and the surface treated copper foil was pulled and peeled from the resin substrate at an angle of 90° at a speed of 50 mm/minute. The measurement was conducted twice and the average value of the measured values was regarded as the peel strength.

Based on the average of the peel strength, peel strength retention (%) was calculated by using the following equation:

Peel strength retention (%)=peel strength (kg/cm) after heating at 150° C. for 72 hours (3 days), 168 hours (7 days), or 240 hours (10 days)/normal peel strength (kg/cm)×100

### (Transmission Loss)

Each of 18-μm-thick samples was attached to a resin substrate (LCP: Liquid Crystal Polymer resin (a copolymer of hydroxybenzoic acid (ester) and hydroxynaphthoic acid (ester)) film, (Vecstar™ CTZ-50μm thick manufactured by KURARAY CO., LTD.)), followed by forming a microstrip line by means of etching so that the characteristic impedance became 50Ω, and the passing power was measured by using a network analyzer HP8720C manufactured by HP to obtain the transmission loss at a frequency of 20 GHz. Note that in Examples 13 to 15, after the surface on the ultra-thin copper layer side of the carrier-attached copper foil was attached to the resin substrate, the carrier was detached, and copper plating was performed so that the total thickness of the ultra-thin copper layer and the copper plating became 18 μm. Afterwards, the transmission loss was measured in the same manner described above. For the evaluation of the transmission loss at a frequency of 20 GHz, less than 3.7 dB/10 cm was evaluated as Excellent, 3.7 dB/10 cm or higher and less than 4.1 dB db/10 cm was evaluated as Good, 4.1 dB/10 cm or higher and less than 5.0 dB db/10 cm was evaluated as Usable, and 5.0 dB/10 cm or higher was evaluated as Bad.

### (Surface Roughness)

Surface roughness Rz

The ten point average roughness Rz of a surface of a side on which the surface treated copper foil has a surface treated layer was measured in accordance with the method specified in JIS B0601-1994 by using a contact type (stylus) roughness meter SP-11 manufactured by Kosaka Laboratory Ltd. The measurement was conducted ten times at different measurement sites under the following conditions: the measurement reference length was 0.8 mm; the evaluation length was 4 mm; the cutoff value was 0.25 mm; and the measuring speed was 0.1 mm/sec. An average value of the ten measured values was regarded as the value of the surface roughness Rz. The measurement was conducted in a direction (TD) perpendicular to the rolling direction when a rolled copper foil was used, or in a direction (TD) perpendicular to a direction to which the electrolytic copper foil moves in an electrolytic copper foil manufacturing machine when an electrolytic copper foil was used. The measurement was conducted ten times at different measurement sites, and an average value of the ten measured values was regarded as the value of the roughness of each of the samples.

Root mean square height Rq, maximum profile peak height Rp, maximum profile valley depth Rv, mean height of profile element Rc, ten point average roughness Rzjis, and arithmetical mean height Ra

The root means square height Rq, the maximum profile peak height Rp, the maximum profile valley depth Rv, the mean height of profile element Rc, the ten point average roughness Rzjis, and the arithmetical mean height Ra of the surface of a side on which surface treated copper foil has a surface treated layer were measured in accordance with the method specified in JIS B0601 2001 by using a laser microscope OLS4000 manufactured by Olympus Corporation. The surface treated copper foil surface was observed at 1000-fold magnification under the conditions of the evaluation length being 647 μm and the cutoff value being 0, and the measurement was carried out in a direction (TD) perpendicular to the rolling direction when a rolled copper foil was used or in a direction (TD) perpendicular to a direction to which an electrolytic copper foil moves in an electrolytic copper foil manufacturing machine when an electrolytic copper foil was used. The measurement was conducted ten times at different measurement sites for each type of roughness and the value for each type of roughness were obtained from an average value of the ten measured values for each type of roughness. Note that the environmental temperature of the measurement at the time of the measurement using the laser microscope was 23 to 25° C.

Evaluation results are provided in Tables 1 and 2.

TABLE 1

| | | ROUGHENING TREATMENT | | | | | | | | | | | |
|---|---|---|---|---|---|---|---|---|---|---|---|---|---|
| | | PLATING | | PLATING | | PLATING | | PLATING | | PLATING | | PLATING | |
| | | TREATMENT 1 | | TREATMENT 2 | | TREATMENT 3 | | TREATMENT 4 | | TREATMENT 5 | | TREATMENT 6 | |
| | | | AMOUNT | | AMOUNT | | AMOUNT | | AMOUNT | | AMOUNT | | AMOUNT |
| | | CURRENT | OF | CURRENT | OF | CURRENT | OF | CURRENT | OF | CURRENT | OF | CURRENT | OF |
| | COPPER | DENSITY | COULOMB | DENSITY | COULOMB | DENSITY | COULOMB | DENSITY | COULOMB | DENSITY | COULOMB | DENSITY | COULOMB |
| | FOIL | (A/dm²) | (As/dm²) | (A/dm²) | (As/dm²) | (A/dm²) | (As/dm²) | (A/dm²) | (As/dm²) | (A/dm²) | (As/dm²) | (A/dm²) | (As/dm²) |
| EXAMPLE 1 | ROLLED | 50-110 | 106 | 6-8 | 31 | 50-110 | 106 | 6-8 | 34 | 6-8 | 32 | 6-8 | 35 |
| | COPPER | | | | | | | | | | | | |
| | FOIL | | | | | | | | | | | | |
| EXAMPLE 2 | ROLLED | 50-110 | 88 | 6-8 | 31 | 50-110 | 88 | 6-8 | 34 | 6-8 | 32 | 6-8 | 35 |
| | COPPER | | | | | | | | | | | | |
| | FOIL | | | | | | | | | | | | |
| EXAMPLE 3 | ROLLED | 50-110 | 91 | 6-8 | 27 | 50-110 | 91 | 6-8 | 27 | 6-8 | 28 | 6-8 | 28 |
| | COPPER | | | | | | | | | | | | |
| | FOIL | | | | | | | | | | | | |
| EXAMPLE 4 | ROLLED | 50-110 | 89 | 6-8 | 25 | 50-110 | 89 | 6-8 | 25 | 6-8 | 26 | 6-8 | 26 |
| | COPPER | | | | | | | | | | | | |
| | FOIL | | | | | | | | | | | | |
| EXAMPLE 5 | ROLLED | 50-110 | 88 | 6-8 | 25 | 50-110 | 88 | 6-8 | 25 | 6-8 | 26 | 6-8 | 26 |
| | COPPER | | | | | | | | | | | | |
| | FOIL | | | | | | | | | | | | |
| EXAMPLE 6 | ELECTRO- | 50-110 | 94 | 6-8 | 21 | 50-110 | 94 | 6-8 | 21 | 6-8 | 22 | 6-8 | 22 |
| | LYTIC | | | | | | | | | | | | |
| | COPPER | | | | | | | | | | | | |
| | FOIL | | | | | | | | | | | | |
| EXAMPLE 7 | ELECTRO- | 50-110 | 83 | 6-8 | 33 | 50-110 | 83 | 6-8 | 35 | 6-8 | 33 | 6-8 | 35 |
| | LYTIC | | | | | | | | | | | | |
| | COPPER | | | | | | | | | | | | |
| | FOIL | | | | | | | | | | | | |
| EXAMPLE 8 | ROLLED | 50-110 | 76 | 6-8 | 33 | 50-110 | 76 | 6-8 | 35 | 6-8 | 34 | 6-8 | 35 |
| | COPPER | | | | | | | | | | | | |
| | FOIL | | | | | | | | | | | | |
| EXAMPLE 9 | ROLLED | 73.3 | 73 | 6.5 | 32 | 73.3 | 73 | 7.0 | 34 | 6.7 | 34 | 7.3 | 35 |
| | COPPER | | | | | | | | | | | | |
| | FOIL | | | | | | | | | | | | |
| EXAMPLE 10 | ROLLED | 50-110 | 87 | 6-8 | 34 | 50-110 | 87 | 6-8 | 34 | 6-8 | 33 | 6-8 | 35 |
| | COPPER | | | | | | | | | | | | |
| | FOIL | | | | | | | | | | | | |
| EXAMPLE 11 | ROLLED | 50-110 | 76 | 6-8 | 31 | 50-110 | 76 | 6-8 | 34 | 6-8 | 32 | 6-8 | 35 |
| | COPPER | | | | | | | | | | | | |
| | FOIL | | | | | | | | | | | | |
| EXAMPLE 12 | ROLLED | 50-110 | 105 | 6-8 | 32 | 50-110 | 105 | 6-8 | 34 | 6-8 | 33 | 6-8 | 35 |
| | COPPER | | | | | | | | | | | | |
| | FOIL | | | | | | | | | | | | |
| EXAMPLE 13 | CARRIER: | 50-110 | 89 | 6-8 | 29 | 50-110 | 89 | 6-8 | 29 | 6-8 | 31 | 6-8 | 31 |
| | ROLLED | | | | | | | | | | | | |
| | COPPER | | | | | | | | | | | | |
| | FOIL | | | | | | | | | | | | |
| EXAMPLE 14 | CARRIER: | 50-110 | 77 | 6-8 | 31 | 50-110 | 77 | 6-8 | 34 | 6-8 | 32 | 6-8 | 35 |
| | ROLLED | | | | | | | | | | | | |
| | COPPER | | | | | | | | | | | | |
| | FOIL | | | | | | | | | | | | |
| EXAMPLE 15 | CARRIER: | 88.4 | 108 | 6.5 | 32 | 88.4 | 108 | 7.0 | 35 | 6.7 | 34 | 7.3 | 35 |
| | ROLLED | | | | | | | | | | | | |
| | COPPER | | | | | | | | | | | | |
| | FOIL | | | | | | | | | | | | |
| COMPARATIVE | ROLLED | 50-110 | 121 | 6-8 | 36 | 50-110 | 121 | 6-8 | 39 | 6-8 | 37 | 6-8 | 40 |
| EXAMPLE 1 | COPPER | | | | | | | | | | | | |
| | FOIL | | | | | | | | | | | | |
| COMPARATIVE | ROLLED | 50-110 | 131 | 6-8 | 38 | 50-110 | 121 | 6-8 | 38 | 6-8 | 40 | 6-8 | 40 |
| EXAMPLE 2 | COPPER | | | | | | | | | | | | |
| | FOIL | | | | | | | | | | | | |
| COMPARATIVE | ROLLED | 30 | 78 | 6-8 | 36 | 30 | 78 | 6-8 | 36 | 6-8 | 36 | 6-8 | 36 |
| EXAMPLE 3 | COPPER | | | | | | | | | | | | |
| | FOIL | | | | | | | | | | | | |
| COMPARATIVE | ELECTRO- | 50-110 | 97 | 6-8 | 25 | 50-110 | 97 | 6-8 | 25 | 6-8 | 26 | 6-8 | 26 |
| EXAMPLE 4 | LYTIC | | | | | | | | | | | | |
| | COPPER | | | | | | | | | | | | |
| | FOIL | | | | | | | | | | | | |
| COMPARATIVE | ELECTRO- | 50-110 | 95 | 6-8 | 22 | 50-110 | 95 | 6-8 | 22 | 6-8 | 22 | 6-8 | 23 |
| EXAMPLE 5 | LYTIC | | | | | | | | | | | | |
| | COPPER | | | | | | | | | | | | |
| | FOIL | | | | | | | | | | | | |
| COMPARATIVE | ELECTRO- | 50-110 | 138 | 6-8 | 40 | 50-110 | 138 | 6-8 | 40 | 6-8 | 40 | 6-8 | 40 |
| EXAMPLE 6 | LYTIC | | | | | | | | | | | | |
| | COPPER | | | | | | | | | | | | |
| | FOIL | | | | | | | | | | | | |
| COMPARATIVE | ROLLED | 30 | 77 | 6-8 | 36 | 30 | 77 | 6-8 | 36 | 6-8 | 36 | 6-8 | 36 |
| EXAMPLE 7 | COPPER | | | | | | | | | | | | |
| | FOIL | | | | | | | | | | | | |
| COMPARATIVE | ELECTRO- | 30 | 115 | 6-8 | 36 | 30 | 115 | 6-8 | 36 | 6-8 | 36 | 6-8 | 36 |
| EXAMPLE 8 | LYTIC | | | | | | | | | | | | |
| | COPPER | | | | | | | | | | | | |
| | FOIL | | | | | | | | | | | | |
| COMPARATIVE | ROLLED | 30 | 99 | 6-8 | 36 | 30 | 99 | 6-8 | 36 | 6-8 | 36 | 6-8 | 36 |
| EXAMPLE 9 | COPPER | | | | | | | | | | | | |
| | FOIL | | | | | | | | | | | | |
| COMPARATIVE | ELECTRO- | 50-110 | 143 | 6-8 | 45 | 50-110 | 143 | 6-8 | 45 | 6-8 | 45 | 6-8 | 45 |
| EXAMPLE 10 | LYTIC | | | | | | | | | | | | |
| | COPPER | | | | | | | | | | | | |
| | FOIL | | | | | | | | | | | | |
| COMPARATIVE | ELECTRO- | 30 | 75 | 6-8 | 36 | 30 | 75 | 6-8 | 36 | 6-8 | 36 | 6-8 | 36 |
| EXAMPLE 11 | LYTIC | | | | | | | | | | | | |
| | COPPER | | | | | | | | | | | | |
| | FOIL | | | | | | | | | | | | |
| COMPARATIVE | ELECTRO- | 30 | 61 | 6-8 | 36 | 30 | 61 | 6-8 | 36 | 6-8 | 36 | 6-8 | 36 |
| EXAMPLE 12 | LYTIC | | | | | | | | | | | | |
| | COPPER | | | | | | | | | | | | |
| | FOIL | | | | | | | | | | | | |

| | SURFACE ROUGHNESS AFTER SURFACE | | | | | | | | |
|---|---|---|---|---|---|---|---|---|---|
| | TREATMENT OF COPPER FOIL | | | | | | | PARTICLE HAVING | |
| | CONTACT | | | | | | | 3 OR MORE | |
| | TYPE | | | | | | | PROJECTIONS | |
| | (STYLUS) | LASER | | | | | | PRESENT/ | PARTICLES/ |
| | RZ[μm] | Rp [μm] | Rv[μm] | Rzjis[μm] | Rc[μm] | Ra[μm] | Rq[μm] | ABSENT | um2 |
| EXAMPLE 1 | 1.28 | 1.56 | 1.56 | 3.11 | 0.96 | 0.38 | 0.48 | PRESENT | 1.7 |
| EXAMPLE 2 | 1.23 | 1.19 | 1.04 | 2.23 | 0.60 | 0.24 | 0.31 | PRESENT | 1.8 |
| EXAMPLE 3 | 1.05 | 1.32 | 1.48 | 2.80 | 0.83 | 0.33 | 0.42 | PRESENT | 1.5 |
| EXAMPLE 4 | 1.03 | 1.26 | 1.35 | 2.46 | 0.80 | 0.29 | 0.39 | PRESENT | 1.5 |
| EXAMPLE 5 | 1.02 | 1.25 | 1.33 | 2.39 | 0.80 | 0.29 | 0.39 | PRESENT | 1.4 |
| EXAMPLE 6 | 1.11 | 1.33 | 1.46 | 2.56 | 0.88 | 0.32 | 0.41 | PRESENT | 2.2 |
| EXAMPLE 7 | 1.15 | 1.21 | 1.16 | 2.09 | 0.78 | 0.30 | 0.36 | PRESENT | 0.7 |
| EXAMPLE 8 | 0.98 | 1.02 | 1.05 | 1.88 | 0.72 | 0.22 | 0.33 | PRESENT | 0.5 |
| EXAMPLE 9 | 0.89 | 0.92 | 0.98 | 1.71 | 0.69 | 0.21 | 0.30 | PRESENT | 0.6 |
| EXAMPLE 10 | 1.06 | 1.21 | 1.31 | 2.35 | 0.76 | 0.27 | 0.32 | PRESENT | 0.5 |
| EXAMPLE 11 | 1.01 | 1.06 | 1.09 | 1.87 | 0.69 | 0.23 | 0.34 | PRESENT | 1.2 |
| EXAMPLE 12 | 1.26 | 1.54 | 1.53 | 3.02 | 0.89 | 0.36 | 0.46 | PRESENT | 1.3 |
| EXAMPLE 13 | 1.09 | 1.25 | 1.35 | 2.42 | 0.78 | 0.28 | 0.33 | PRESENT | 0.5 |
| EXAMPLE 14 | 1.04 | 1.09 | 1.12 | 1.93 | 0.71 | 0.24 | 0.35 | PRESENT | 1.2 |
| EXAMPLE 15 | 1.30 | 1.59 | 1.58 | 3.11 | 0.92 | 0.37 | 0.47 | PRESENT | 1.3 |
| COMPARATIVE | 1.33 | 1.63 | 1.81 | 3.44 | 1.05 | 0.41 | 0.53 | PRESENT | 1.6 |
| EXAMPLE 1 | | | | | | | | | |
| COMPARATIVE | 1.64 | 1.60 | 2.03 | 3.63 | 1.10 | 0.43 | 0.54 | PRESENT | 1.6 |
| EXAMPLE 2 | | | | | | | | | |
| COMPARATIVE | 0.97 | 1.01 | 0.97 | 1.99 | 0.61 | 0.23 | 0.36 | ABSENT | 0 |
| EXAMPLE 3 | | | | | | | | | |
| COMPARATIVE | 1.06 | 1.33 | 1.44 | 2.66 | 0.81 | 0.35 | 0.43 | PRESENT | 1.6 |
| EXAMPLE 4 | | | | | | | | | |
| COMPARATIVE | 1.13 | 1.32 | 1.49 | 2.61 | 0.91 | 0.33 | 0.42 | PRESENT | 2.1 |
| EXAMPLE 5 | | | | | | | | | |
| COMPARATIVE | 2.01 | 2.03 | 2.22 | 4.12 | 1.34 | 0.52 | 0.61 | PRESENT | 1.1 |
| EXAMPLE 6 | | | | | | | | | |
| COMPARATIVE | 0.99 | 1.00 | 1.03 | 1.90 | 0.71 | 0.21 | 0.32 | PRESENT | 0.3 |
| EXAMPLE 7 | | | | | | | | | |
| COMPARATIVE | 1.31 | 1.60 | 1.79 | 3.49 | 1.02 | 0.41 | 0.52 | ABSENT | 0 |
| EXAMPLE 8 | | | | | | | | | |
| COMPARATIVE | 1.07 | 1.36 | 1.52 | 2.81 | 0.86 | 0.35 | 0.44 | PRESENT | 0.1 |
| EXAMPLE 9 | | | | | | | | | |
| COMPARATIVE | 2.26 | 2.23 | 2.54 | 4.23 | 1.35 | 0.54 | 0.62 | PRESENT | 0.5 |
| EXAMPLE 10 | | | | | | | | | |
| COMPARATIVE | 0.90 | 0.99 | 1.01 | 1.72 | 0.63 | 0.24 | 0.31 | ABSENT | 0 |
| EXAMPLE 11 | | | | | | | | | |
| COMPARATIVE | 0.52 | 0.66 | 0.84 | 0.98 | 0.48 | 0.19 | 0.24 | ABSENT | 0 |
| EXAMPLE 12 | | | | | | | | | |

TABLE 2

| | | | | | | | | | ADHESION BETWEEN RESIN AND SURFACE TREATED COPPER FOIL | | | | | | | TRANS- |
|---|---|---|---|---|---|---|---|---|---|---|---|---|---|---|---|---|
| | | | DEPOSITION AMOUNT OF EACH | | | | | | | 3 DAYS AT 150° C. | | 7 DAYS AT 150° C. | | 10 DAYS AT 150° C. | | MISSION |
| | | | ELEMENT ON ROUGHENED SURFACE | | | | | | | | PEEL | | PEEL | | PEEL | CHARAC- |
| | HEAT- | RUST- | | | | | | Co + Ni + | | | STRENGTH | | STRENGTH | | STRENGTH | TERISTIC |
| | RESISTANT | PROOFING | Co | Ni | Mo | Zn | Cr | Mo | NORMAL | | RETENTION | | RETENTION | | RETENTION | dB/cm |
| | LAYER | LAYER | [μg/dm²] | [μg/dm²] | [μg/dm²] | [μg/dm²] | [μg/dm²] | [μg/dm²] | kg/cm | kg/cm | (%) | kg/cm | (%) | kg/cm | (%) | @20 GHz |
| EXAMPLE 1 | — | — | 0 | 0 | 0 | 47 | 173 | 0 | 1.16 | 1.15 | 99.8 | 1.15 | 99.3 | 1.10 | 95.0 | 0.41 |
| EXAMPLE 2 | — | — | 0 | 0 | 0 | 59 | 178 | 0 | 1.23 | 1.23 | 99.8 | 1.23 | 100.2 | 1.11 | 90.0 | 0.40 |
| EXAMPLE 3 | — | — | 0 | 0 | 0 | 76 | 166 | 0 | 1.21 | 1.14 | 94.9 | 1.11 | 92.4 | 1.10 | 91.2 | 0.38 |
| EXAMPLE 4 | Ni—Co | — | 350 | 160 | 0 | 66 | 160 | 510 | 1.19 | — | — | — | — | 1.16 | 97.5 | 0.41 |
| | PLATING | | | | | | | | | | | | | | | |
| EXAMPLE 5 | Ni—Co | — | 770 | 210 | 0 | 45 | 133 | 980 | 1.16 | — | — | — | — | 1.14 | 98.3 | 0.44 |
| | PLATING | | | | | | | | | | | | | | | |
| EXAMPLE 6 | — | — | 0 | 0 | 0 | 55 | 143 | 0 | 1.31 | — | — | — | — | 1.15 | 87.8 | 0.42 |
| EXAMPLE 7 | Co—Mo | — | 290 | 0 | 220 | 80 | 70 | 510 | 1.01 | — | — | — | — | 0.82 | 81.2 | 0.40 |
| | PLATING | | | | | | | | | | | | | | | |
| EXAMPLE 8 | — | — | 0 | 0 | 0 | 110 | 45 | 0 | 1.02 | — | — | — | — | 0.81 | 79.4 | 0.37 |
| EXAMPLE 9 | Ni—Co | — | 620 | 100 | 0 | 130 | 56 | 720 | 0.91 | — | — | — | — | 0.80 | 87.9 | 0.35 |
| | PLATING | | | | | | | | | | | | | | | |
| EXAMPLE 10 | Ni—Mo | — | 0 | 250 | 100 | 92 | 31 | 350 | 1.08 | — | — | — | — | 0.89 | 82.4 | 0.37 |
| | PLATING | | | | | | | | | | | | | | | |
| EXAMPLE 11 | — | — | 0 | 0 | 0 | 210 | 67 | 0 | 1.17 | — | — | — | — | 1.08 | 92.3 | 0.38 |
| EXAMPLE 12 | — | Zn—Ni | 0 | 640 | 0 | 108 | 49 | 640 | 1.12 | 1.15 | 102.9 | 1.15 | 102.4 | 1.09 | 97.3 | 0.43 |
| | | PLATING | | | | | | | | | | | | | | |
| EXAMPLE 13 | Ni—Mo | — | 0 | 250 | 100 | 92 | 31 | 350 | 1.11 | — | — | — | — | 0.87 | 78.4 | 0.38 |
| | PLATING | | | | | | | | | | | | | | | |
| EXAMPLE 14 | — | — | 0 | 0 | 0 | 210 | 67 | 0 | 1.18 | — | — | — | — | 1.08 | 91.5 | 0.39 |
| EXAMPLE 15 | — | Zn—Ni | 0 | 640 | 0 | 108 | 49 | 640 | 1.12 | 1.14 | 101.8 | 1.14 | 101.8 | 1.10 | 98.2 | 0.44 |
| | | PLATING | | | | | | | | | | | | | | |
| COMPARATIVE | — | — | 0 | 0 | 0 | 58 | 161 | 0 | 1.18 | 1.20 | 101.9 | 1.17 | 99.5 | 1.14 | 97.4 | 0.45 |
| EXAMPLE 1 | | | | | | | | | | | | | | | | |
| COMPARATIVE | — | — | 0 | 0 | 0 | 55 | 149 | 0 | 1.14 | 1.13 | 98.8 | 1.10 | 96.4 | 1.13 | 98.3 | 0.46 |
| EXAMPLE 2 | | | | | | | | | | | | | | | | |
| COMPARATIVE | — | — | 0 | 0 | 0 | 40 | 165 | 0 | 0.51 | — | — | — | — | 0.26 | 51.0 | 0.35 |
| EXAMPLE 3 | | | | | | | | | | | | | | | | |
| COMPARATIVE | Co—Mo | | 1540 | 660 | 160 | 75 | 159 | 2360 | 1.24 | 1.14 | 92.3 | 1.11 | 89.8 | 1.19 | 96.0 | 0.49 |
| EXAMPLE 4 | PLATING | | | | | | | | | | | | | | | |
| COMPARATIVE | Co | | 2620 | 0 | 0 | 61 | 142 | 2620 | 1.35 | — | — | — | — | 1.21 | 89.6 | 0.53 |
| EXAMPLE 5 | PLATING | | | | | | | | | | | | | | | |
| COMPARATIVE | — | — | 0 | 0 | 0 | 63 | 177 | 0 | 1.21 | 1.20 | 98.9 | 1.17 | 96.6 | 1.09 | 90.1 | 0.54 |
| EXAMPLE 6 | | | | | | | | | | | | | | | | |
| COMPARATIVE | — | — | 0 | 0 | 0 | 106 | 42 | 0 | 0.77 | — | — | — | — | 0.54 | 70.1 | 0.36 |
| EXAMPLE 7 | | | | | | | | | | | | | | | | |
| COMPARATIVE | — | — | 0 | 0 | 0 | 60 | 149 | 0 | 0.73 | 1.20 | 164.0 | 1.17 | 160.2 | 0.42 | 57.5 | 0.45 |
| EXAMPLE 8 | | | | | | | | | | | | | | | | |
| COMPARATIVE | — | — | 0 | 0 | 0 | 81 | 130 | 0 | 0.82 | 1.14 | 139.6 | 1.11 | 135.8 | 0.41 | 50.0 | 0.39 |
| EXAMPLE 9 | | | | | | | | | | | | | | | | |
| COMPARATIVE | Ni—Mo | — | 0 | 160 | 1200 | 56 | 99 | 1360 | 1.03 | 1.20 | 116.2 | 1.17 | 113.5 | 0.82 | 79.6 | 0.52 |
| EXAMPLE 10 | PLATING | | | | | | | | | | | | | | | |
| COMPARATIVE | Co—Mo | — | 230 | 0 | 95 | 150 | 163 | 325 | 0.45 | — | — | — | — | 0.21 | 46.7 | 0.37 |
| EXAMPLE 11 | PLATING | | | | | | | | | | | | | | | |
| COMPARATIVE | — | Zn—Ni | 0 | 200 | 0 | 80 | 32 | 200 | 0.30 | — | — | — | — | 0.08 | 26.7 | 0.38 |
| EXAMPLE 12 | | PLATING | | | | | | | | | | | | | | |

When the surface treated copper foil or the carrier-attached copper foil described in Examples 1 to 15 in which the total deposition amount of Co, Ni, and Mo was 1000 μg/dm² or less in the surface treated layer, the surface treated layer included a particle having three or more projections, the number of the particles per μm² in the surface treated layer was 0.4 or more, and the surface roughness Rz on the surface treated layer side measured by a contact type (stylus) roughness meter was 1.3 μm or less, or the surface roughness Rp on the surface treated layer side measured by a laser microscope was 1.59 μm or less, or the surface roughness Rv on the surface treated layer side measured by a laser microscope was 1.75 μm or less, or the surface roughness Rzjis on the surface treated layer side measured by a laser microscope was 3.3 μm or less, or the surface roughness Rc on the surface treated layer side measured by a laser microscope was 1.0 μm or less, or the surface roughness Ra on the surface treated layer side measured by a laser microscope was 0.4 μm or less, or the surface roughness Rq on the surface treated layer side measured by a laser microscope was 0.5 μm or less was used, favorable results were obtained in terms of the adhesion between the resin and the surface treated copper foil and the transmission characteristics.

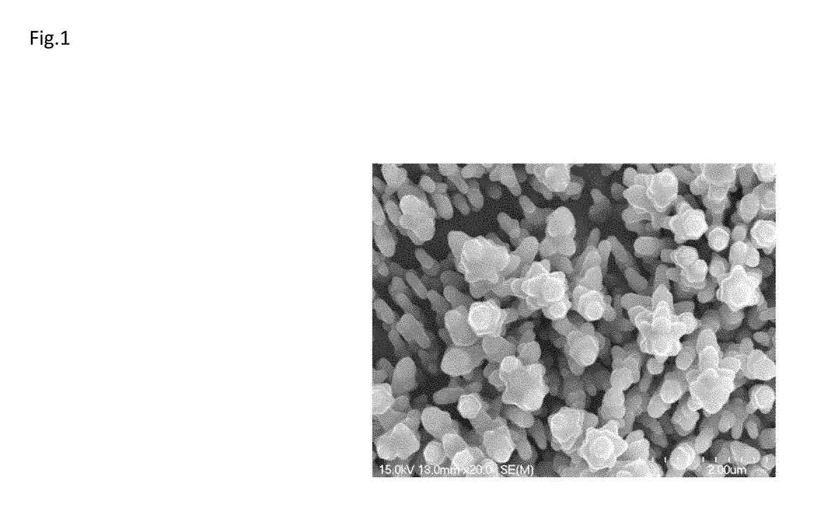

FIG. 1 is a photography of the microscopic observation of the surface of the surface treated layer in Example 3.

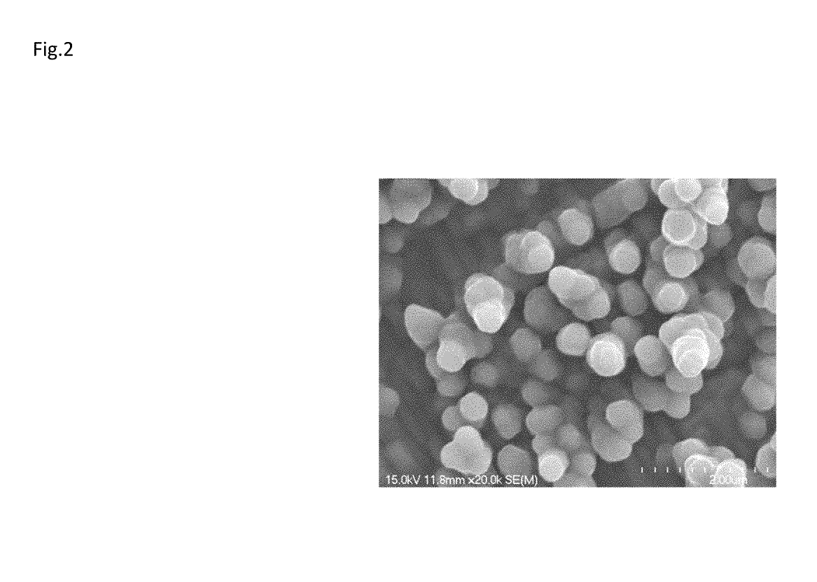

FIG. 2 is a photography of the microscopic observation of the surface of the surface treated layer in Comparative Example 9.

It should be noted that this application is based upon and claims the benefit of priority of the prior Japanese Patent Application No. 2017-73280, filed on Mar. 31, 2017, the entire contents of which are incorporated herein by reference.

1. A surface treated copper foil, comprising:
a copper foil; and
a surface treated layer formed on at least one surface of the copper foil,
wherein a total deposition amount of Co, Ni, and Mo is 1000 μg/dm² or less in the surface treated layer,
the surface treated layer includes a particle having three or more projections, a number of the particles per μm² in the surface treated layer being 0.4 or more, and
the surface treated copper foil satisfies any one or more of items (1-1) to (1-7) below:
(1-1) surface roughness Rz on a side of the surface treated layer measured by a contact type roughness meter is 1.3 μm or less;
(1-2) surface roughness Rp on the side of the surface treated layer measured by a laser microscope is 1.59 μm or less;
(1-3) surface roughness Rv on the side of the surface treated layer measured by a laser microscope is 1.75 μm or less;
(1-4) surface roughness Rzjis on the side of the surface treated layer measured by a laser microscope is 3.3 μm or less;
(1-5) surface roughness Rc on the side of the surface treated layer measured by a laser microscope is 1.0 μm or less;
(1-6) surface roughness Ra on the side of the surface treated layer measured by a laser microscope is 0.4 μm or less; and
(1-7) surface roughness Rq on the side of the surface treated layer measured by a laser microscope is 0.5 μm or less.

2. The surface treated copper foil according to claim 1,
wherein the surface treated copper foil satisfies any one or more of items (2-1) to (2-7) below:
(2-1) surface roughness Rz on the side of the surface treated layer measured by a contact type roughness meter is 0.89 μm or more;
(2-2) surface roughness Rp on the side of the surface treated layer measured by a laser microscope is 0.80 μm or more;
(2-3) surface roughness Rv on the side of the surface treated layer measured by a laser microscope is 0.98 μm or more;
(2-4) surface roughness Rzjis on the side of the surface treated layer measured by a laser microscope is 1.70 μm or more;
(2-5) surface roughness Rc on the side of the surface treated layer measured by a laser microscope is 0.60 μm or more;
(2-6) surface roughness Ra on the side of the surface treated layer measured by a laser microscope is 0.21 μm or more; and
(2-7) surface roughness Rq on the side of the surface treated layer measured by a laser microscope is 0.30 μm or more.

3. The surface treated copper foil according to claim 2,
wherein the surface treated layer includes a particle having three or more projections, a number of the particles per μm² in the surface treated layer being 0.7 or more.

4. The surface treated copper foil according to claim 3,
wherein the surface treated layer includes a particle having three or more projections, the number of the particles per μm² in the surface treated layer being 1.0 or more.

5. The surface treated copper foil according to claim 1,
wherein the total deposition amount of Co, Ni, and Mo is 800 μg/dm² or less in the surface treated layer.

6. The surface treated copper foil according to claim 1,
wherein the total deposition amount of Co, Ni, and Mo is 600 μg/dm² or less in the surface treated layer.

7. The surface treated copper foil according to claim 2,
wherein the total deposition amount of Co, Ni, and Mo is 600 μg/dm² or less in the surface treated layer.

8. The surface treated copper foil according to claim 4,
wherein the total deposition amount of Co, Ni, and Mo is 600 μg/dm² or less in the surface treated layer.

9. The surface treated copper foil according to claim 1,
wherein a deposition amount of Co is 400 μg/dm² or less in the surface treated layer.

10. The surface treated copper foil according to claim 9,
wherein the deposition amount of Co is 320 μg/dm² or less in the surface treated layer.

11. The surface treated copper foil according to claim 10,
wherein the deposition amount of Co is 240 μg/dm² or less in the surface treated layer.

12. The surface treated copper foil according to claim 1,
wherein a deposition amount of Ni is 600 μg/dm² or less in the surface treated layer.

13. The surface treated copper foil according to claim 12,
wherein the deposition amount of Ni is 480 μg/dm² or less in the surface treated layer.

14. The surface treated copper foil according to claim 13,
wherein the deposition amount of Ni is 360 μg/dm² or less in the surface treated layer.

15. The surface treated copper foil according to claim 1,
wherein a deposition amount of Mo is 600 μg/dm² or less in the surface treated layer.

16. The surface treated copper foil according to claim 15,
wherein the deposition amount of Mo is 480 μg/dm² or less in the surface treated layer.

17. The surface treated copper foil according to claim 16,
wherein the deposition amount of Mo is 360 μg/dm² or less in the surface treated layer.

18. The surface treated copper foil according to claim 1,
wherein the surface treated layer includes a roughened layer.

19. The surface treated copper foil according to claim 1,
wherein a resin layer is provided on the surface treated layer.

20. A method of use of a surface treated copper foil, comprising using the surface treated copper foil according to claim 1 for a circuit of a high frequency circuit board used under a condition that a signal frequency is 1 GHz or higher.

21. A carrier-attached copper foil, comprising
a carrier;
an intermediate layer; and
an ultra-thin copper layer,
wherein the ultra-thin copper layer is the surface treated copper foil according to claim 1.

22. A laminate, comprising:
a resin substrate; and
any one of (22-1) and (22-2) below:
(22-1) the surface treated copper foil according to claims 1; and
(22-2) a carrier-attached copper foil having a carrier, an intermediate layer, and an ultra-thin copper layer, the ultra-thin copper layer being the surface treated copper foil according to claim 1.

23. A method for manufacturing a printed wiring board comprising
using any one of (23-1) and (23-2) below;
(23-1) the surface treated copper foil according to claims 1; and
(22-2) a carrier-attached copper foil having a carrier, an intermediate layer, and an ultra-thin copper layer, the ultra-thin copper layer being the surface treated copper foil according to claim 1.

24. A method for manufacturing an electronic device comprising using a printed wiring board manufactured by the method according to claim 23.

25. A method for manufacturing a printed wiring board, comprising:
preparing the carrier-attached copper foil according to claim 21 and an insulating substrate;
laminating the carrier-attached copper foil and the insulating substrate;
forming a copper-clad laminate by removing a carrier of the carrier-attached copper foil after the laminating the carrier-attached copper foil and the insulating substrate; and
forming a circuit by means of any one selected from a semi-additive method, a subtractive method, a partly-additive method, and a modified semi-additive method.

26. A method for manufacturing a printed wiring board, comprising:
forming a circuit on a surface on the ultra-thin copper layer side or a surface on the carrier side of the carrier-attached copper foil according to claim 21;
forming a resin layer on the surface on the ultra-thin copper layer side or the surface on the carrier side of the carrier-attached copper foil so that the circuit is buried;
forming a circuit on the resin layer;
detaching the carrier or the ultra-thin copper layer after the forming the circuit on the resin layer; and
exposing the circuit that is formed on the surface on the ultra-thin copper layer side or the surface on the carrier side and is buried in the resin layer as a result of removing the ultra-thin copper layer or the carrier after the detaching the carrier or the ultra-thin copper layer.
